(19) United States
(12) Patent Application Publication
(10) Pub. No.: US 2026/0013059 A1
(43) Pub. Date: Jan. 8, 2026

(54) STACKED BODY, DISPLAY DEVICE AND MEMBER FOR STACKED BODY

(71) Applicant: DAI NIPPON PRINTING CO., LTD., Tokyo (JP)

(72) Inventors: Keisuke WAKITA, Tokyo (JP); Takanori MAEDA, Tokyo (JP); Yosuke WADA, Tokyo (JP); Atsushi WASHIO, Tokyo (JP); Makoto NANAUMI, Tokyo (JP); Kazuyoshi SATAKE, Tokyo (JP)

(21) Appl. No.: 18/878,609

(22) PCT Filed: Jun. 29, 2023
(86) PCT No.: PCT/JP2023/024141

§ 371 Date: Sep. 26, 2025

(30) Foreign Application Priority Data
Jun. 29, 2022 (JP) 2022-104526

(51) Int. Cl. H05K 5/03; B32B 17/10

(52) U.S. Cl. CPC H05K 5/03; B32B 17/10; B32B 2250/04; B32B 2307/546; B32B 2307/7376; B32B 2457/20

(57) ABSTRACT

The present disclosure provides a stacked body comprising a first layer, a second layer, and a third layer in this order, wherein a recovery at a cross-section of the second layer, according to a nanoindentation method, is 10% or more.

### TECHNICAL FIELD

The present disclosure relates to a stacked body, a display device, and a member for a stacked body.

### BACKGROUND ART

In display devices, for example, glass or resin cover members are conventionally used for protecting the display devices. The glass cover members have properties such as high surface hardness so that it is hardly scuffed, and high transparency, while the resin cover materials have properties such as lightweight and resistant to breakage. In recent years, flexible displays such as foldable displays, rollable displays, and bendable displays have been actively developed, and among them, the foldable displays, that is, display devices that can be folded have been developed.

In the display devices that can be folded, the cover members must also bend in accordance with the movement of the display devices, so the cover members that can be folded are applied. In the case of resin cover members, colorless and transparent polyimide and polyamideimide films have been developed by devising the chemical structures. Also, in the case of glass cover members, studies are being conducted on cover members that can be folded by thinning glass such as Ultra-Thin Glass (UTG). Among the glasses, glass referred to as chemically strengthened glass has particularly high bending resistance, and the glass is not likely to be cracked by incorporating an expanding stress on the glass surface so that the microscopic scratches occurred on the glass surface do not grow when folded.

For example, Patent Document 1 discloses an optical stacked body comprising a front panel, a predetermined first pressure-sensitive adhesive layer formed using a first pressure-sensitive adhesive composition, a polarizing plate, a predetermined second pressure-sensitive adhesive layer formed using a second pressure-sensitive adhesive composition, and a rear panel, in this order, and a resin film including a glass plate and a hard coating layer is disclosed as the front panel.

### CITATION LIST

### Patent Document

Patent Document 1: Japanese Patent Application Laid-Open (JP-A) No. 2021-140147

### SUMMARY OF DISCLOSURE

### Technical Problem

Among the flexible display devices, foldable displays are required to prevent display defects even if they are bent repeatedly, and stacked bodies disposed on the surface of the flexible display devices are required to have bending resistance that does not cause peeling or cracking when they are bent repeatedly. Generally, as a test to evaluate the bending resistance of a stacked body, a U-shaped bending test, as shown in FIGS. 14, has been conventionally used. In the U-shaped bending test, for example as shown in FIG. 14(a), a short side portion 10P and a short side portion 100 facing the short side portion 10P of the stacked body 10 are respectively fixed by parallelly arranged fixing portions 100A, 100B. As shown in FIG. 14(a), the fixing portion 100B is movable by sliding in horizontal direction. Then, as shown in FIGS. 14(b) to (c), by moving the fixing portion 100B so as to be closer to the fixing portion 100 A, the stacked body 10 is bent into a U-shape. In such a U-shaped bending test, as shown in FIGS. 14(a) to (c), by moving the fixing portion 100B so as to be closer to the fixing portion 100 A, since the sample (stacked body 10) is bent into a U-shape, bending load is applied to the whole of the sample (stacked body 10).

Meanwhile, when a foldable display is actually used, the bent portion may be local, and stress may be concentrated to the local bent portion. The inventors of the present disclosure found that, even when a stacked body was evaluated as having good bending resistance in the U-shaped bending test, there was a problem that peeling between the layers included in the stacked body would occur when the bending load was concentrated at the local bent portion and such bending was repeated. Specifically, it was found that, in a stacked body including a first layer, a second layer, and a third layer, and the second layer adheres the first layer and the third layer, the second layer is peeled off from the first layer or the third layer in some cases. Also, in a stacked body including a first layer, a second layer, a fourth layer, and a third layer, and the second layer and fourth layer adhere the first layer and the third layer, when the stacked body is bent locally repeatedly, there is a problem that the second layer is peeled off from the first layer, or the third layer is peeled off from the fourth layer.

Incidentally, in order to suppress the generation of bubbles in the pressure-sensitive adhesive layer when an optical stacked body is bent and maintained for a certain period of time, Patent Document 1 discloses to set the shear recovery of a first pressure-sensitive adhesive layer and the second pressure-sensitive adhesive layer, according to a viscoelasticity measuring device, in a predetermined range. However, Patent Document 1 does not describe the above described problem relating the peeling of the pressure-sensitive adhesive layer, which occurs when the bending load is repeatedly concentrated to the local bent portion.

The present disclosure has been made in view of the above circumstances, and an object of the present disclosure is to provide a stacked body with good bending resistance, even when the stacked body is locally bent.

### Solution to Problem

One embodiment of the present disclosure provides a stacked body comprising a first layer, a second layer, and a third layer in this order, wherein a recovery at a cross-section of the second layer, according to a nanoindentation method, is 10% or more.

One embodiment of the present disclosure provides a stacked body comprising a first layer, a second layer, a fourth layer, and a third layer in this order, wherein a recovery at a cross-section of the second layer and the fourth layer, according to a nanoindentation method, is respectively 10% or more.

Also, a display device comprising: a display panel, and the stacked body described above disposed on an observer side of the display panel is provided.

Further, a member for a stacked body used for the stacked body described above, wherein the first layer and the second layer are stacked is provided.

### Advantageous Effects of Disclosure

The present disclosure exhibits an effect that it is possible to provide a stacked body with good bending resistance, even when the stacked body is locally bent.

### BRIEF DESCRIPTION OF DRAWINGS

FIG. 1 is a schematic cross-sectional view exemplifying a stacked body in the first embodiment in the present disclosure.

FIG. 2 is a schematic cross-sectional view exemplifying a stacked body in the first embodiment in the present disclosure.

FIG. 3 is a schematic cross-sectional view exemplifying a stacked body in the first embodiment in the present disclosure.

FIG. 4 is a schematic cross-sectional view exemplifying a stacked body in the first embodiment in the present disclosure.

FIG. 5 are schematic cross-sectional views exemplifying a stacked body in the first embodiment in the present disclosure.

FIG. 6 is a schematic cross-sectional view exemplifying a stacked body in the second embodiment in the present disclosure.

FIG. 7 is a schematic cross-sectional view exemplifying a stacked body in the second embodiment in the present disclosure.

FIG. 8 is a schematic cross-sectional view exemplifying a stacked body in the second embodiment in the present disclosure.

FIG. 9 is a schematic cross-sectional view exemplifying a stacked body in the second embodiment in the present disclosure.

FIG. 10 are schematic cross-sectional views exemplifying a stacked body in the second embodiment in the present disclosure.

FIG. 11 is a schematic cross-sectional view explaining a display device in the present disclosure.

FIG. 12 is a schematic cross-sectional view explaining a member for a stacked body in the present disclosure.

FIG. 13 is a load-displacement curve measured according to a nanoindentation method.

FIG. 14 are schematic views explaining a U-shaped bending test.

FIG. 15 are schematic views explaining a clamshell-type bending test.

FIG. 16 is a schematic view explaining an impact test.

### DESCRIPTION OF EMBODIMENTS

Embodiments in the present disclosure are hereinafter explained with reference to, for example, drawings. However, the present disclosure is enforceable in a variety of different forms, and thus should not be taken as is limited to the contents described in the embodiments exemplified as below. Also, the drawings may show the features of the present disclosure such as width, thickness, and shape of each part schematically comparing to the actual form in order to explain the present disclosure more clearly in some cases; however, it is merely an example, and thus does not limit the interpretation of the present disclosure. Also, in the present descriptions and each drawing, for the factor same as that described in the figure already explained, the same reference sign is indicated and the detailed explanation thereof may be omitted.

In the present descriptions, in expressing an aspect wherein some member is disposed on the other member, when described as merely “on” or “below”, unless otherwise stated, it includes both of the following cases: a case wherein some member is disposed directly on or directly below the other member so as to be in contact with the other member, and a case wherein some member is disposed on the upper side or the lower side of the other member via yet another member. Also, in the present descriptions, on the occasion of expressing an aspect wherein some member is disposed on the surface of the other member, when described as merely “on the surface side” or “on the surface”, unless otherwise stated, it includes both of the following cases: a case wherein some member is disposed directly on or directly below the other member so as to be in contact with the other member, and a case wherein some member is disposed on the upper side or the lower side of the other member via yet another member.

A stacked body, a display device, and a member for a display device in the present disclosure are hereinafter described in detail.

### A-1. Stacked Body (First Embodiment)

The stacked body in the first embodiment of the present disclosure comprises a first layer, a second layer, and a third layer in this order, wherein a recovery at a cross-section of the second layer, according to a nanoindentation method, is a predetermined value or more.

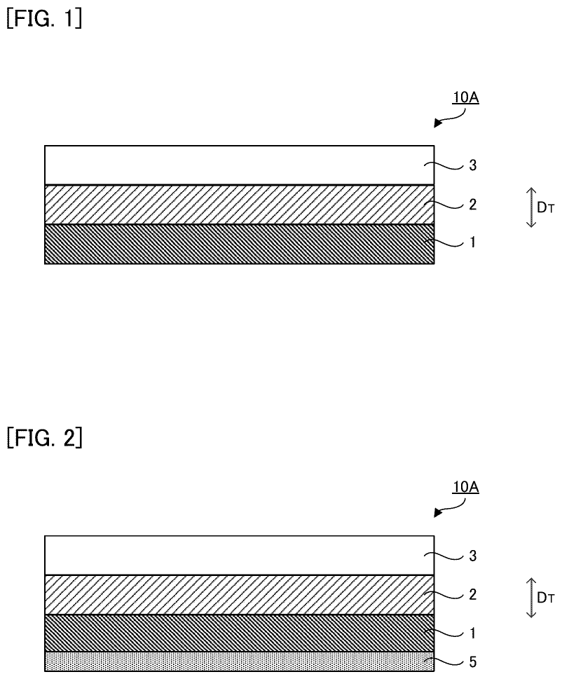

FIG. 1 is a schematic cross-sectional view illustrating an example of a stacked body in the first embodiment in the present disclosure. As shown in FIG. 1, the stacked body 10A in the present embodiment includes a first layer 1, a second layer 2, and a third layer 3, in this order in the thickness direction Dr. In the present embodiment, the recovery at a cross-section of the second layer 2, according to a nanoindentation method, is a predetermined value or more.

As described above, when used, for example, in a foldable display, as for a stacked body including a first layer, a second layer, and a third layer, and the second layer adheres the first layer and the third layer, when the stacked body is bent locally repeatedly, there is a problem that the second layer is peeled off from the first layer or the third layer. In this phenomenon, it is believed that, the harder the layer (for example, a layer with high composite elastic modulus), the more prone to be peeled off, since the shear stress concentrated in the bent portion is higher.

However, the inventors of the present disclosure have found out that the likelihood of peeling of the second layer is not dependent on the composite elastic modulus. Further, the inventors of the present disclosure have carried out diligent studies and found that, by making the recovery at a cross-section of the second layer, according to a nanoindentation method, a predetermined value or more, the peeling of the second layer can be suppressed so as to exhibit excellent bending resistance, even when locally bent.

The reason therefore is presumed as follows. In other words, in the bending motion in the bent portion, the second layer is displaced toward the stretching direction (hereinafter referred to as stretching displacement) during the transition from the flat condition to the bent condition, and displaced toward the compressing direction (referred to as compressing displacement) when returning to the flat condition, from the bent condition. In this case, when the recovery is extremely high during the displacement described above, although the shear stress is applied during the initial stretching displacement, it is assumed that large shear stress is not applied, since the force to return to the original shape during the next compressing displacement is sufficient. Further, it is assumed that the same condition will continue in subsequent bending. In other words, when the second layer has high recovery, a peeling hardly occurs even when the second layer has high composite elastic modulus.

Meanwhile, when the recovery is low, although the shear stress similar to the above is applied during the initial stretching displacement, the shear stress is also applied during the next compressing displacement returning to the original shape, since the second layer is plastically deformed in the bent condition during the compressing displacement. Further, it is assumed that the similar shear stress will continue to be applied in subsequent bending.

Particularly, when the local bending motion is continued with a small radius of curvature, it is assumed that the shear stress described above to be applied will be noticeable.

As described above, when the bending is local, it is assumed that a peeling is not likely to occur when the recovery at a cross-section of the second layer, according to a nanoindentation method is a predetermined value or more.

The stacked body in the first embodiment in the present disclosure is hereinafter described in detail for each layer.

### 1. Second Layer

The second layer in the present embodiment is disposed between the first layer and third layer, and has a function as a joining layer joining the first layer and third layer. In the present embodiment, the recovery at a cross-section in the thickness direction of the second layer, according to a nanoindentation method, is a predetermined value or more. The cross-section in the thickness direction of the second layer is the cross-sectional surface obtained by cutting the second layer in the thickness direction D_{T} (the stacked direction of the stacked body).

### (1) Recovery According to Nanoindentation Method

The recovery at a cross-section of the second layer, according to a nanoindentation method is usually 10% or more, may be 20% or more, may be 30% or more, may be 40% or more, and may be 50% or more. Meanwhile, the recovery is, for example, 80% or less, may be 70% or less, and may be 60% or less.

Specifically, the recovery is preferably in a range of 10% or more and 80% or less, more preferably in a range of 20% or more and 70% or less, and particularly preferably in a range of 30% or more and 60% or less.

The “recovery” in the present disclosure is the value obtained from the load-displacement curve measured using a surface coated film property tester (Triboindenter TI950 from Bruker Corporation) according to the nanoindentation method.

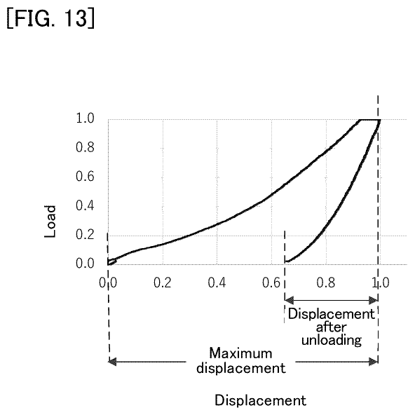

The load-displacement curve is obtained by measuring the relationship between the load and displacement from pushing-in (compression) a Berkovich indenter (material: a triangular pyramid diamond), in the vertical direction under the following conditions, to the cross-section of the second layer in a thickness direction of a measurement sample prepared by the following method, until the indenter is removed (unloading). FIG. 13 shows a typical load-displacement curve.

### <Method for Preparing Measurement Sample>

At first, a block wherein a stacked body cut out to a size of 1 mm×10 mm is embedded in an embedding resin is prepared, and a uniform section with a thickness of 50 nm or more and 100 nm or less without a hole, for example, is cut out from this block by a common section preparing method. For the preparation of the section, for example, “Ultramicrotome EM UC7” (from Leica Microsystems, Inc.) may be used. Then, the remaining of the block from which this uniform section without a hole, for example, is cut out is used as a measurement sample.

Then, onto the cross-section of such the measurement sample obtained by cutting out the section, a Berkovich indenter (a triangular pyramid, TI-0039 from Bruker Corporation) as the indenter is compressed perpendicularly onto the center of the cross-section of the second layer, under the following conditions, taking 10 seconds, until the maximum compressing load of 25 μN. Then, after maintaining the load at a constant level to relieve the residual stress, the load is unloaded over 10 seconds. Here, the position where the Berkovich indenter is compressed is preferably an approximate center, in the thickness direction, of the second layer. The approximate center means that, when the thickness of the second layer is defined as T [μm], the deviation from the center in the thickness direction of the second layer is within +0.1T. Specifically, the deviation from the center of the second layer in the thickness direction is preferably +0.1 μm.

### <Measurement Conditions for Load-Displacement Curve>

Used indenter: a Berkovich indenter (a triangular pyramid, model number: TI-0039 from Bruker Corporation).
Compression condition: load control method

### (Measurement Conditions 1)

Maximum load: 25 UN.
Load application time: 10 seconds (0 μN to 25 μN, speed: 2.5 μN/sec).
Retention time: 5 seconds
Unloading time: 10 seconds (25 μN to 0 μN, speed: −2.5 μN/sec)

Incidentally, if the compressing depth at the maximum load, when measuring under the measurement conditions 1 is carried out, is 500 nm or more, the conditions are changed, and the measurement is carried out under the following measurement conditions 2.

### (Measurement Conditions 2)

Maximum load: 3 μN.
Load application time: 10 seconds (0 μN to 3 μN, speed: 0.3 μN/second).
Retention time: 5 seconds
Unloading time: 10 seconds (3 μN to 0 μN, speed:-0.3 μN/second)
When the indenter is pushed-in even after the load is applied, the retention time is adjusted within the range of 5 seconds to 50 seconds.

The displacement after unloading and the maximum displacement are calculated from the obtained load-displacement curve data. Incidentally, the displacement after unloading and the maximum displacement are shown in the load-displacement curve in FIG. 13. The recovery is calculated from the displacement after unloading and the maximum displacement according to the following formula.

Recovery [%]=(displacement after unloading/maximum displacement)×100

The recovery in the present specification is a value measured at a temperature of 23±5° C. and a relative humidity of 40 to 65%. Also, the recovery is the arithmetic average value of the recovery obtained for the cross-section of the second layer at 10 locations, for a stacked body.

Examples of the method for making the recovery at a cross-section of the second layer, according to a nanoindentation method, to be 10% or more may include methods such as increasing the molecular weight of the resin; increasing the breaking strength of the resin; increasing the breaking elongation of the resin; and increasing the glass transition temperature (Tg) of the resin.

### (2) Composite Elastic Modulus

In the present embodiment, the composite elastic modulus of the second layer may be, for example, 0.01 GPa or more, preferably 0.05 GPa or more, and further preferably more than 0.05 GPa. When the composite elastic modulus of the second layer is the above value or more, it is preferable to improve the scratch resistance of the stacked body. Also, the composite elastic modulus of the second layer is, for example, 7.0 GPa or less, and may be 6.0 GPa or less.

The composite elastic modulus of the second layer in the present embodiment is obtained from the following formula (1) using the contact projection area Ap, by analyzing the load-displacement curve obtained by the above method. In the present specification, the composite elastic modulus of the second layer means an arithmetic average value of the measurement value at ten locations. Also, the atmosphere for measuring the composite elastic modulus is at temperature of 23° C.±5° C. and humidity of 40% to 65%.

$$\begin{matrix}[ Mathematic 1 ] & \\ {E}_{r} = \frac{S \sqrt{π}}{2 \sqrt{{A}_{p}}} & ( 1 )\end{matrix}$$

(In the formula (1), Aₚ is a contact projection area, Eᵣ is the composite elastic modulus of the second layer, and S is a contact stiffness and is the slope of the unloading curve.)

(3) Indentation Hardness H_{IT}/Composite Elastic Modulus Eᵣ

For the second layer in the present embodiment, the ratio (indentation hardness H_{IT}/composite elastic modulus Eᵣ) of the indentation hardness H_{IT} (MPa) with respect to the composite elastic modulus Eᵣ (GPa) may be, for example, more than 30, and may be 40 or more. Meanwhile, the ratio is, for example, 85 or less, and may be 70 or less. When indentation hardness Hur/composite elastic modulus Eᵣ is the above value or more, the bending resistance tends to improve. Incidentally, in the case of high hardness materials such as glass having a composite modulus of approximately 70 GPa, brittle fracture tends to occur when the H_{IT}/Eᵣ is high. However, in the region where the composite elastic modulus is several GPa or less, the bending resistance tends to be good when the H_{IT}/Eᵣ is the above value or more.

Incidentally, by analyzing the load-displacement curve prepared above, the indentation hardness Hur can be calculated as a value obtained by dividing the maximum compressing load Pₘₐₓ (N) by the contact projection area Aₚ (mm²) where the indenter and the film are in contact with each other at that time (following formula (2)). The indentation hardness H_{IT} is an arithmetic average value of the value obtained by measuring at ten places.

$${H}_{IT} = {P}_{max} / {A}_{p} \qquad ( 2 )$$

Here, Aₚ is a contact projection area wherein the indenter tip curvature is corrected by Oliver-Pharr method, using a reference sample fused quartz (5-0098 from Bruker Corporation).

### (4) Material

The second layer preferably includes a resin. The resin included in the second layer is not particularly limited as long as the recovery of the second layer is the recovery described above. Also, the second layer has a function as a joining layer joining the first layer and third layer.

The second layer is preferably a so-called heat sealing layer. Examples of the resin that can be used for the heat sealing layer may include thermoplastic resins. Examples of the thermoplastic resin may include acrylic resins, polyacrylpolyols, urethane resins, vinyl chloride based resins, vinyl acetate based resins, vinyl chloride-vinyl acetate copolymers, styrene-acrylic copolymer, acrylic-vinyl acetate copolymers, polyester resins, olefin resin, amide resins, cyanoacrylate resins, epoxy resins, polyimide based resins, cellulose based resins, polycarbonate based resins, and polyethylene naphthalate based resins; and these may be used alone, or multiple types of these may be combined and used. Incidentally, the polyester urethane resins and polyether urethane resins are included in the urethane resins.

Among them, examples of the preferable material that can achieve the recovery of 10% or more may include polyester resins, urethane resins and olefin resins.

Also, when the second layer is a heat sealing layer, the heat-sensitive adhesive composition forming the heat sealing layer may further include a curing agent. Thereby, heat resistance and close adhesiveness may be improved. Also, by adding the curing agent, the composite elastic modulus of the second layer may be adjusted. Examples of the curing agent may include isocyanate based curing agents, epoxy based curing agents, and melamine based curing agents. One type of the curing agents may be used alone, and two types or more may be used in combination. When the heat-sensitive adhesive composition includes a curing agent, the second layer will include the cured product of the heat-sensitive adhesive composition.

Also, the second layer may include additives if necessary. Examples of the additives may include a light stabilizer, ultraviolet absorbers, infrared absorbers, antioxidants, plasticizers, coupling agents, antifoaming agents, fillers, inorganic or organic particles configured to adjust the refractive index, antistatic agents, coloring agents such as a blue pigment and a violet pigments, a leveling agent, a surfactant, an easy lubricant, various sensitizers, a flame retardant, an adhesive imparting agent, a polymerization inhibitor, and a surface modifier. These additives may be selected and used as appropriate from those of regular use. The content of the additive may be set accordingly. Among them, the composition for a second layer preferably includes a silane coupling agent to increase close adhesiveness to the third layer.

Meanwhile, the second layer may be a so-called pressure-sensitive adhesive layer. The pressure-sensitive adhesive used for the second resin layer is not particularly limited if it is a pressure-sensitive adhesive capable of obtaining a pressure-sensitive adhesive layer having transparency, and for example, OCA (optically clear adhesive may be used. Specific examples thereof may include acrylic based pressure-sensitive adhesives, silicone based pressure-sensitive adhesives, urethane based pressure-sensitive adhesives, rubber based pressure-sensitive adhesives, polyvinyl ether based pressure-sensitive adhesives, and polyvinyl acetate based pressure-sensitive adhesives. When the second layer is a pressure-sensitive adhesive layer, the glass transition temperature of the pressure-sensitive adhesive layer is preferably −15° or more, and more preferably −10° or more. Here, the glass transition temperature in the present specification means a value measured by a method based on the peak top value of loss tangent (tan d) (DMA method). Also, the loss tangent is determined by the value of the loss elastic modulus/storage elastic modulus. These elastic moduli are obtained by measuring the stress, using a dynamic viscoelastic measuring device, when a force is applied to the pressure-sensitive adhesive layer at a constant frequency.

### (5) Others

The thickness of the second layer is preferably, for example 1 μm or more, further preferably 1.5 μm or more, and particularly preferably 2.0 μm or more. Meanwhile, the thickness is preferably 100 μm or less, further preferably 75 μm or less, and particularly preferably 50 μm or less. Specifically, the thickness is preferably in a range of 1 μm or more and 100 μm or less, further preferably in a range of 1.5 μm or more and 75 μm or less, and particularly in a range of 2.0 μm or more and, 50 μm or less. When the thickness of the second layer is too thick, the bending resistance may be deteriorated. Meanwhile, when the thickness of the second layer is too thin, the adhesiveness may not be secured so as to be peeled off.

Also, when the second layer is a heat sealing layer, the thickness is preferably, 1 μm or more, further preferably 1.5 μm or more, and particularly preferably 2.0 μm or more. Meanwhile, the thickness is preferably 100 μm or less, more preferably 50 μm or less, further preferably 25 μm or less, and particularly preferably 20 μm or less. Specifically, the thickness is preferably in a range of 1 μm or more and 100 μm or less, further preferably in a range of 1.0 μm or more and 25 μm or less, and particularly preferably in a range of 2.0 μm or more and, 20 μm or less.

Also, when the second layer is a pressure-sensitive adhesive layer, the thickness is preferably, 30 μm or more, and more preferably 50 μm or more. When the second layer is a pressure-sensitive adhesive layer, if the thickness of the second layer is too thin, the bending resistance may be deteriorated. Meanwhile, the thickness is preferably 100 μm or less, and further preferably 75 μm or less. Specifically, the thickness is preferably in a range of 30 μm or more and 100 μm or less, and further preferably in a range of 50 μm or more and 75 μm or less.

Here, the thickness of the second layer may be the average value of the thickness of arbitrary 10 points obtained by measuring from the thickness directional cross-section of the stacked body by observing with a transmission electron microscope (TEM), a scanning electron microscope (SEM) or a scanning transmission electron microscope (STEM). Incidentally, the same may be applied to the measuring methods of the thickness of other layers included in the stacked body, unless otherwise stated.

The second layer preferably has transparency. Specifically, the total light transmittance of the second layer is preferably 85% or more, more preferably 88% or more, and further preferably 90% or more.

Here, the total light transmittance of the second layer may be measured according to JIS K7361-1, and may be measure with, for example, a haze meter HM150 from Murakami Color Research Laboratory Co., Ltd. Hereinafter, the same may be applied to the measuring methods of the total light transmittance of other layers.

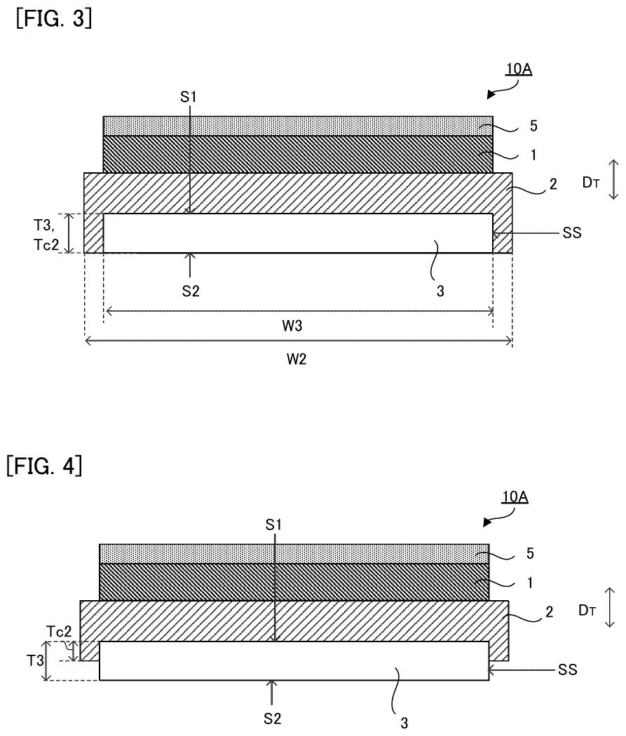

As shown in FIG. 3 and FIG. 4, the third layer 3 usually includes a first main surface on the second layer side, a second main surface opposite to the first main surface, and the side surface SS different from the first main surface S1 and the second main surface S2. In the present embodiment, the second layer 2 preferably covers the side surface SS of the third layer 3. In this case, the width W2 of the second layer 2 is larger than the width W3 of the third layer 3.

Here, the case where the third layer is a glass substrate is described. Microcracks easily occur in the glass substrates during processing, and particularly, microcracks easily occur at the edge portions of the glass substrates during cutting process of the glass substrates. When there are microcracks in the glass substrate, cracks starting from these microcracks are likely to occur. Also, when chemically strengthened glass is used as the glass substrate, impact resistance and bending resistance can be improved. However, even in this case, when the glass substrate constituted from chemically strengthened glass is subjected to a cutting process, the strength of the side surface of the glass substrate is decreased, since a compression stress layer, formed on the surface of the chemically strengthened glass, does not exist on the cut surface, that is, the side surface of the glass substrate.

When the third layer is a glass substrate, by the second layer covering the side surface of the third layer, the strength of the side surface of the glass substrate can be increased. Also, the microcrack on the side surface of the glass substrate can be filled by the second layer, and the strength of the side surface of the glass substrate can be increased. Therefore, the impact resistance of the edge portion of the glass stacked body can be improved.

Also, the degree of coverage of the side surface of the third layer by the second layer is not particularly limited as long as the strength of the side surface of the third layer can be increased by covering the side surface of the third layer by the second layer. For example, the entire surface of the side surface of the third layer may be covered by the second layer, and a part of the side surface of the third layer may be covered by the second layer. Specifically, as shown in FIG. 3, the entire portion of the side surface SS in the thickness direction Dr may be covered by the second layer 2, and as shown in FIG. 4, a part of the side surface SS in the thickness direction Dr may be covered by the second layer 2.

The degree of coverage of the side surface of the third layer by the second layer in the thickness direction Dr, specifically, the ratio (Tc2/T3) of the thickness Tc2 of the side surface of the third layer covered by the second layer with respect to the thickness T3 of the third layer is, for example, 0.5 or more, may be 0.6 or more, and may be 0.7 or more. Meanwhile, the ratio is, for example, 1.0 or less, may be 0.9 or less, and may be 0.8 or less. Specifically, the above ratio (Tc2/T3) is, for example, 0.5 or more and 1.0 or less, may be 0.6 or more and 0.9 or less, and may be 0.7 or more and 0.8 or less. When the ratio is in the above range, the impact resistance of the side surface of the glass substrate is improved.

The shape of the glass substrate is usually a cuboid, and it is a hexahedron. Also, even when the glass substrate is beveled, for example, the shape of the glass substrate can usually be considered a cuboid and roughly hexahedron. In this case, the glass substrate includes a first surface and a second surface facing each other, and four side surfaces. In such cases, as for the degree of coverage of the side surface of the glass substrate by the second layer, at least one side surface out of the four side surfaces of the glass substrate has only to be covered by the second layer. That is, in this case, one side surface out of the four side surfaces of the glass substrate may be covered by the second layer; two side surfaces may be covered by the second layer; three side surfaces may be covered by the second layer; and four side surfaces may be covered by the second layer.

Among them, facing two side surfaces out of the four side surfaces of the glass substrate are preferably covered by the second layer; and two side surfaces approximately parallel to the bending direction of the glass stacked body, out of the four side surfaces of the glass substrate, are preferably covered by the second layer. The reason therefor is to suppress cracking in the bent portion when the glass stacked body is bent, and to improve the bending resistance.

### 2. First Layer

The first layer usually includes resin. Also, the first layer has optical transmissivity, and when the stacked body in the present embodiment is disposed on the observer side of the display panel of a display device, the first layer is disposed on the observer side than the third layer described later. The first layer can also function as an impact absorbing layer having impact absorbing properties, and as a scattering prevention layer that suppresses the scattering of glass when the glass substrate is broken, for example, when the third layer is a glass substrate. When the third layer is a glass substrate, for example, by disposing the first layer on the glass substrate, when an impact is imparted to the stacked body, the impact is absorbed by the first layer so that the glass substrate is suppressed from being cracked, and the impact resistance may be improved. Further, the first layer can suppress the scattering of glass, even if the glass substrate is broken.

The first layer has transparency, and specifically, the total light transmittance of the first resin layer is preferably 85% or more, more preferably 88% or more, and further preferably 90% or more.

The composite elastic modulus of the first layer is, for example 6.0 GPa or more, and preferably 6.5 GPa or more. By setting the composite elastic modulus of the first layer in the above range, the impact resistance and scratch resistance may be improved by the first layer. Examples of the resin included in such the first layer may include the resins described below. Meanwhile, the composite elastic modulus of the first layer is, for example 70 GPa or less, and preferably 10 GPa or less. Specifically, the composite elastic modulus of the first layer is preferably, for example, 6.0 GPa or more and 70 GPa or less, and more preferably 6.5 GPa or more and 10 GPa or less. The method for measuring the composite elastic modulus of the first layer may be similar to the method for measuring the composite elastic modulus of the second layer described above.

### (a) Resin

Specific examples of the resin included in the first layer may include polyester based resins, polyimide based resins, cellulose based resins, cyclo-olefin polymer (COP), epoxy resins, polyurethane, acrylic based resins, cyclo-olefins (COP) and polycarbonates (PC). The reason therefor is to obtain a resin layer having transparency and impact absorbing properties. One type of these resins may be used alone, and two types or more may be used in a combination.

Examples of the polyester based resin may include polyethylene terephthalate (PET), polypropylene terephthalate, polybutylene terephthalate, and polyethylene naphthalate (PEN). The polyimide based resin refers to a polymer including an imide bond in the main chain. Examples of the polyimide based resin may include polyimide, polyamideimide, polyesterimide, and polyetherimide. Examples of the cellulose based resin may include triacetylcellulose (TAC). Examples of the acrylic based resin may include poly(meth)methyl acrylate, and poly(meth)ethyl acrylate. Among them, from the viewpoint of having bending resistance, excellent hardness and transparency, the polyimide based resin is preferable.

The first layer is preferably a resin film including resins selected from the above group of resins.

### (b) Additives

The first layer may further include an additive if necessary. Examples of the additives may include, ultraviolet absorbers, a light stabilizer, antioxidants, inorganic particles, silica fillers for facilitating winding, surfactants for improving film forming property and antifoaming property, and adhesive improving agents.

When the first layer includes an ultraviolet absorber, the deterioration of the first layer due to ultraviolet rays may be suppressed. In particular, when the first layer includes polyimide, color change over time of the resin layer including polyimide may be suppressed. Also, in display device including a stacked body, the deterioration of a member disposed on the display panel side than the stacked body, such as a polarizer, due to ultraviolet ray may be suppressed.

Examples of the ultraviolet absorber included in the first layer may include triazine based ultraviolet absorbers; benzophenone based ultraviolet absorbers such as hydroxybenzophenone based ultraviolet absorbers; and benzotriazole based ultraviolet absorbers.

Also, the ultraviolet absorber is preferably a polymer or oligomer. This is because the bleed-out of the ultraviolet absorber, when the stacked body is bent repeatedly, may be suppressed. Examples of such ultraviolet absorber may include polymers or oligomers including a triazine skeleton, a benzophenone skeleton, or a benzotriazole skeleton; and specifically, it is preferably ones obtained by thermally copolymerizing methyl methacrylate (MMA), and (meth)acrylate including a benzotriazole skeleton or a benzophenone skeleton, at an arbitrary ratio.

The content of the ultraviolet absorber in the first layer is not particularly limited, and is preferably, for example 1% by mass or more and 6% by mass or less, and more preferably 2% by mass or more and 5% by mass or less. When the content of the ultraviolet absorber is too low, the effect due to the ultraviolet absorber may not be sufficiently obtained. Also, when the content of the ultraviolet absorber is too high, the resin layer may be notably colored, or the hardness of the resin layer may decrease.

### 3. Third Layer

The third layer is not particularly limited as long as it has transparency; and examples thereof may include glass substrates and resin substrates. In the present embodiment, the glass substrate is preferable.

### (1) Glass Substrate

The glass constituting the glass substrate is not particularly limited as long as it has transparency; and examples thereof may include silicate glass and silica glass. Among them, borosilicate glass, aluminosilicate glass, and aluminoborosilicate glass are preferable, and alkali-free glass is more preferable. Examples of the commercial products of the glass substrate may include ultra-thin plate glass G-Leaf from Nippon Electric Glass Co., Ltd., and ultra-thin film glass from Matsunami Glass Ind., Ltd.

Also, the glass constituting the glass substrate is preferably a chemically strengthened glass. The chemically strengthened glass is preferable since it has excellent mechanical strength and may be made thin accordingly. The chemically strengthened glass is typically a glass wherein mechanical properties are strengthened by a chemical method by partially exchanging ionic species, such as by replacing sodium with potassium, in the vicinity of the surface of glass, and includes a compressive stress layer on the surface.

Examples of the glass constituting the chemically strengthened glass substrate may include aluminosilicate glass, soda-lime glass, borosilicate glass, lead glass, alkali barium glass, and aluminoborosilicate glass.

Examples of the commercial products of the chemically strengthened glass substrate may include Gorilla Glass from Corning Incorporated, Dragontrail from AGC Inc., and chemically strengthened glass from Schott Ag.

The thickness of the glass substrate is preferably, for example, 115 μm or less and further preferably 110 μm or less. Meanwhile, the thickness is preferably 15 μm or more, further preferably 20 μm or more, and particularly preferably 25 μm or more. The thickness of the glass substrate in the present embodiment is preferably 15 μm or more and 115 μm or less, further preferably 20 μm or more and 110 μm or less.

When the thickness of the glass substrate is in the above range, excellent flexibility may be obtained, and at the same time, sufficient hardness may be obtained. It is also possible to suppress curling of the stacked body for a display device. Furthermore, it is preferable in terms of reducing the weight of the stacked body for a display device.

### (2) Resin Substrate

The resin included in the resin substrate is not particularly limited if it is resin capable of obtaining a resin substrate having transparency.

The composite elastic modulus of the resin substrate is, for example 6.0 GPa or more, and preferably 6.5 GPa or more. Meanwhile, the composite elastic modulus of the resin substrate is, for example 70 GPa or less, and preferably 10 GPa or less. Specifically, the composite elastic modulus of the resin substrate is preferably, for example, 6.0 GPa or more and 70 GPa or less, and more preferably 6.5 GPa or more and 10 GPa or less. The method for measuring the composite elastic modulus of the resin substrate may be similar to the method for measuring the composite elastic modulus of the second layer described above.

Examples of the resin included in the resin substrate may include a polyimide based resin, a polyamide based resin, and a polyester based resin. Examples of the polyimide based resin may include polyimide, polyamideimide, polyetherimide, and polyesterimide. Examples of the polyester based resin may include polyethylene terephthalate, polypropylene terephthalate, polybutylene terephthalate, and polyethylene naphthalate. Among them, from the viewpoint of having bending resistance, excellent hardness and transparency, the polyimide based resin, the polyamide based resin, or a mixture thereof is preferable, and the polyimide based resin is more preferable.

The polyimide based resin is not particularly limited as long as it is able to obtain a resin substrate having transparency; and among the above, polyimide and polyamideimide are preferably used. Flexibility and bending resistance may be increased, and since the refractive index is relatively high, it makes easier to adjust the reflectivity.

The thickness of the resin substrate is preferably, for example, 10 μm or more and 100 μm or less, and more preferably 20 μm or more and 80 μm or less. When the thickness of the resin substrate is in the above range, excellent flexibility may be obtained, and at the same time, sufficient hardness may be obtained. It is also possible to suppress curling of the stacked body for a display device. Furthermore, it is preferable in terms of reducing the weight of the stacked body for a display device.

### 4. Other Layers

The stacked body in the present embodiment may include another layer, in addition to the first layer, the second layer and the third layer described above. The member for a display device in the present embodiment may further include a functional layer on the surface of the first layer that is opposite side to the third layer, or between the first layer and second layer. Examples of the functional layer, disposed on the surface of the first layer that is opposite side to the third layer, may include a hard coating layer, a protective layer, an antireflection layer, and an antiglare layer. Examples of the functional layer, disposed between the first layer and second layer, may include a decorative layer, and a primer layer.

The functional layer may be a single layer, and may include a plurality of layers. Also, the functional layer may be a layer having a single function, and may include a plurality of layers having functions different from each other. As the functional layer disposed on the surface of the first layer that is opposite side to the third layer, the stacked body in the present embodiment may include, for example, a hard coating layer and a protective layer, in order from the first layer side.

### (1) Hard Coating Layer

As shown in FIG. 2 for example, the stacked body in the present embodiment preferably further includes a hard coating layer 5 on the surface of the first layer 1 that is opposite side to the third layer 3. The hard coating layer is a member configured to increase the surface hardness. By disposing the hard coating layer, scratch resistance may be improved.

### (a) Properties of Hard Coating Layer

Here, “hard coating layer” is a member configured to increase the surface hardness. Specifically, in a configuration wherein the member for a display device in the present embodiment includes a hard coating layer, “hard coating layer” is referred to one exhibiting a hardness of “H” or more in the pencil hardness test according to JIS K 5600-5-4 (1999).

When the stacked body in the present embodiment includes the hard coating layer on the surface of the first layer that is opposite side to the third layer, the pencil hardness of the hard coating layer side surface of the stacked body is preferably H or more, more preferably 2H or more, and further preferably 3H or more.

Here, the pencil hardness is measured by the pencil hardness test specified by JIS K5600-5-4 (1999). Specifically, using a pencil for the test specified by JIS-S-6006, the pencil hardness test specified by JIS K5600-5-4 (1999) is carried out to the hard coating layer side surface of the member for a display device, and the pencil hardness may be determined by evaluating the highest pencil hardness at which the sample is not bruised. The measurement conditions may be angle of 45°, load of 750 g, testing rate of 0.5 mm/second or more and 1 mm/second or less, and temperature of 23±2° C. As the pencil hardness tester, for example, a pencil scratch hardness tester from Toyo Seiki Seisaku-sho, Ltd. may be used.

### (b) Configuration of Hard Coating Layer

The hard coating layer may be a single layer, and may have a multi-layered structure of two layers or more. When the hard coating layer has the multi-layered structure, in order to improve the surface hardness, and also to improve the balance of bending resistance and elastic modulus, the hard coating layer preferably includes a layer configured to satisfy the pencil hardness and a layer configured to satisfy the dynamic bending test (a layer configured to satisfy the scratch resistance).

### (c) Material of Hard Coating Layer

As a material of the hard coating layer, for example, organic materials, inorganic materials, and organic-inorganic composite materials may be used.

Among the above, the material of the hard coating layer is preferably organic materials. Specifically, the hard coating layer preferably includes a cured product of a resin composition including a polymerizable compound. The cured product of a resin composition including a polymerizable compound may be obtained by carrying out a polymerization reaction of a polymerizable compound, by a known method using a polymerization initiator if necessary.

### (i) Polymerizable Compound

The polymerizable compound includes at least one polymerizable functional group in the molecule. As the polymerizable compound, for example, at least one type of radical polymerizable compound and cation polymerizable compound may be used.

The radical polymerizable compound is a compound including a radical polymerizable group. The radical polymerizable group included in the radical polymerizable compound may be any functional group capable of generating a radical polymerization reaction, and is not particularly limited; and examples thereof may include a group including a carbon-carbon unsaturated double bond, and specific examples thereof may include a vinyl group and a (meth) acryloyl group. Incidentally, when the radical polymerizable compound includes two or more radical polymerizable groups, these radical polymerizable groups may be the same, and may be different from each other.

The number of radical polymerizable groups included in one molecule of the radical polymerizable compound is preferably two or more, and more preferably three or more, from the viewpoint of improving the hardness of the hard coating layer.

The cation polymerizable compound is a compound including a cation polymerizable group. The cation polymerizable group included in the cation polymerizable compound may be a functional group capable of generating a cation polymerization reaction, and is not particularly limited; and examples thereof may include epoxy groups, oxetanyl groups, and vinyl ether groups. Incidentally, when the cation polymerizable compound includes two or more cation polymerizable groups, these cation polymerizable groups may be the same, and may be different from each other.

The number of the cation polymerizable groups included in one molecule of the cation polymerizable compound is preferably two or more, and more preferably three or more, from the viewpoint of improving hardness of the hard coating layer.

Also, among the above, as a cation polymerizable compound, a compound including at least one type of an epoxy group and an oxetanyl group as a cation polymerizable group is preferable, and a compound including two or more of at least one type of epoxy groups and oxetanyl groups in one molecule is more preferable. A cyclic ether group such as an epoxy group and an oxetanyl group is preferable from the viewpoint that shrinkage associated with the polymerization reaction is small. Also, a compound including the epoxy group among the cyclic ether groups has advantages in that compounds having various structure may be easily obtained; the durability of the obtained hard coating layer is not adversely affected; and the compatibility with the radical polymerizable compound may be easily controlled. Also, the oxetanyl group among the cyclic ether groups has advantages in that the degree of polymerization is high compared with the epoxy group; the toxicity is low; and when the obtained hard coating layer is combined with a compound including an epoxy group, the network forming rate obtained from the cationic polymerizable compound in the coating film is accelerated, and an independent network is formed without leaving unreacted monomers in the film even in a region mixed with the radical polymerizable compound.

### (ii) Polymerization Initiator

The resin composition may include a polymerization initiator if necessary. As the polymerization initiator, a radical polymerization initiator, a cation polymerization initiator, and a radical and cation polymerization initiator may be appropriately selected and used. These polymerization initiators are decomposed by at least one type of light irradiation and heating to generate radicals or cations to cause radical polymerization and cation polymerization to proceed. Incidentally, all of the polymerization initiator may be decomposed and may not be left in the hard coating layer, in some cases.

Specific examples of the radical polymerization initiator, and the cation polymerization initiator may include those described in, for example, JP-A No. 2018-104682.

(iii) Particles

The hard coating layer preferably includes inorganic or organic particles, and more preferably includes inorganic fine particles. By the hard coating layer including the particles, hardness may be improved.

Examples of the inorganic particle may include metal oxide particles such as silica (SiO₂), aluminum oxide, zirconia, titania, zinc oxide, germanium oxide, indium oxide, tin oxide, indium tin oxide (ITO), antimony oxide, and cerium oxide; metal fluoride particles such as magnesium fluoride and sodium fluoride; metal particles; metal sulfide particles; and metal nitride particles. Among them, metal oxide particles are preferable, at least one type selected from silica particles and aluminum oxide particles are more preferable, and silica particles are further preferable. The reason therefor is to obtain excellent hardness.

The hardness of the hard coating layer may be controlled by adjusting the size and content of the inorganic particles. For example, the content of the silica particles is preferably 25 parts by mass or more, and 60 parts by mass or less, with respect to 100 parts by mass of the polymerizable compound.

### (iv) Ultraviolet Absorber

The hard coating layer may include an ultraviolet absorber. Deterioration of the first layer due to ultraviolet rays may be suppressed. In particular, when the first layer includes polyimide, color change over time of the first layer including polyimide may be suppressed. Also, in a display device including a member for a display device, the deterioration of a member disposed on the display panel side than the member for a display device, such as a polarizer, due to ultraviolet ray may be suppressed.

Among them, the peak of the absorption wavelength, in absorbance measurement, of the ultraviolet absorber included in the hard coating layer preferably exist in 300 nm or more and 390 nm or less, more preferably 320 nm or more and 370 nm or less, and further preferably 330 nm or more and 370 nm or less. Such an ultraviolet absorber is able to absorb ultraviolet ray in UVA range efficiently, meanwhile, by shifting the peak wavelength from the absorption wavelength of 250 nm of the initiator for curing the hard coating layer, a hard coating layer having an ultraviolet ray absorbing ability may be formed without inhibiting the curing of the hard coating layer.

Among them, from the viewpoint of preventing the coloring due to the ultraviolet absorber, the peak of the absorption wavelength of the ultraviolet absorber is preferably 380 nm or less.

Incidentally, the absorption of the ultraviolet absorber may be measured using, for example, an ultraviolet-visible-near infrared spectrophotometer (such as V-7100 from JASCO Corporation).

The ultraviolet absorber may be similar to the ultraviolet absorbers used for the first layer described above.

Among them, from the viewpoint of suppressing the deterioration of the first layer due to ultraviolet ray, one type or more of the ultraviolet absorber selected from the group consisting of hydroxybenzophenone based ultraviolet absorbers and benzotriazole based ultraviolet absorbers is preferable, and one type or more of the ultraviolet absorber selected from the group consisting of hydroxybenzophenone based ultraviolet absorbers is more preferable.

From the viewpoint of suppressing the haze due to the mixing of the ultraviolet absorber, the content of the ultraviolet absorber in the hard coating layer is preferably, for example, 10% by mass or less, and more preferably 7% by mass or less. Also, from the viewpoint of suppressing the deterioration of the first layer due to ultraviolet ray and improving the durability, the content of the ultraviolet absorber in the hard coating layer is preferably 1% by mass or more and 6% by mass or less, and more preferably 2% by mass or more and 5% by mass or less.

### (v) Antifoulant

The hard coating layer may include an antifoulant. The member for a display device may be imparted with an antifouling property.

The antifoulant is not particularly limited, and examples thereof may include a silicone based antifoulant, a fluorine based antifoulant, and a silicone based and fluorine based antifoulant. Also, the antifoulant may be an acrylic based antifoulant. One type of the antifoulant may be used alone, and two types or more may be used as a mixture.

A fingerprint is not likely to be marked (inconspicuous) on the hard coating layer including a silicone based antifoulant or a fluorine based antifoulant, and is easily wiped off. Also, when the silicone based antifoulant or the fluorine based antifoulant is included, since the surface tension when applying a curable resin composition for a hard coating layer may be decreased, leveling property is excellent, so that the appearance of the obtained hard coating layer will be excellent.

Also, the hard coating layer including the silicone based antifoulant is excellent in sliding property, and excellent in scratch resistance. In a display device provided with a member for a display device including a hard coating layer including such a silicone based antifoulant, since the sliding property when it is touched with a finger or a stylus pen is excellent, the texture is improved.

The content of the antifoulant is preferably, for example, 0.01 parts by mass or more and 3.0 parts by mass or less, with respect to 100 parts by mass of the resin component. When the content of the antifoulant is too low, there may be cases where sufficient antifouling property may not be imparted to the hard coating layer. Also, when the content of the antifoulant is too high, the hardness of the hard coating layer may be decreased.

### (vi) Other Additives

The hard coating layer may further include an additive if necessary. The additive is not particularly limited, and is appropriately selected according to the function to be imparted to the hard coating layer. Examples thereof may include inorganic or organic particles configured to adjust the refractive index, infrared absorbers, antiglare agents, antifoulants, antistatic agents, coloring agents such as blue pigments and violet pigments, leveling agents, surfactants, easy lubricants, various sensitizers, flame retardants, adhesive imparting agents, polymerization inhibitors, antioxidants, light stabilizers, and surface modifiers.

### (d) Thickness of Hard Coating Layer

The thickness of the hard coating layer may be appropriately selected according to the material of the hard coating layer, the function of the hard coating layer and the use application of the stacked body. When the material of the hard coating layer is an organic material, for example, the thickness of the hard coating layer is preferably 2 μm or more and 50 μm or less, more preferably 3 μm or more and 30 μm or less, further preferably 5 μm or more and 20 μm or less, and particularly preferably 6 μm or more and 10 μm or less. Also, for example, when the material of the hard coating layer is an inorganic material, the thickness of the hard coating layer may be approximately several tens of nanometers. When the thickness of hard coating layer is in the above range, a member for a display device having excellent bending resistance may be obtained, as well as sufficient hardness as the hard coating layer may be obtained.

### (e) Method for Forming Hard Coating Layer

Examples of the method for forming a hard coating layer is appropriately selected according to the material, for example, of the hard coating layer, and may include a method wherein the first layer is coated with a curable resin composition for a hard coating layer including the polymerizable compound, for example, and cured; a vapor deposition method; and a sputtering method.

The curable resin composition for a hard coating layer includes a polymerizable compound, and as necessary, may further include, for example, polymerization initiators, particles, ultraviolet absorbers, solvent, and additives.

The method for applying the curable resin composition for a hard coating layer on the first layer is not particularly limited as long as it is capable of applying with an intended thickness, and examples thereof may include a general coating method such as a gravure coating method, a gravure reverse coating method, a gravure offset coating method, a spin coating method, a roll coating method, a reverse roll coating method, a blade coating method, a dip coating method, and a screen printing method. Also, a transfer method may also be used as a method for forming a coating film of a resin composition for a hard coating layer.

The solvent is removed from the coating film of the curable resin composition for a hard coating layer by drying as necessary. Examples of the drying method may include a reduced-pressure drying method, drying by heating, and a combination of these drying methods. For example, the drying may be carried out by heating at temperature of 30° C. or more and 120° C. or less for 10 seconds or more and 180 seconds or less.

The method for curing the coating film of the curable resin composition for a hard coating layer is appropriately selected according to the polymerizable group of the polymerizable compound, and for example, at least one of a light irradiation, and a heating may be used.

### (2) Protective Layer

The stacked body in the present embodiment may further include a protective layer on the surface of the first layer that is opposite side to the second layer.

The protective layer has transparency. Specifically, the total light transmittance of the protective layer is preferably 85% or more, more preferably 88% or more, and further preferably 90% or more.

The protective layer is not particularly limited as long as it has transparency; and, for example, it may include resin. The resin included in the protective layer is not particularly limited if it is resin capable of obtaining a protective layer having transparency, and commonly used resins may be used.

Examples of the method for disposing a protective layer on one surface of the first layer may include a method wherein a protective film is used as a protective layer, and the first layer and protective film are adhered via a pressure-sensitive adhesive layer; or a method wherein a protective layer is formed on the first layer.

### (3) Primer Layer

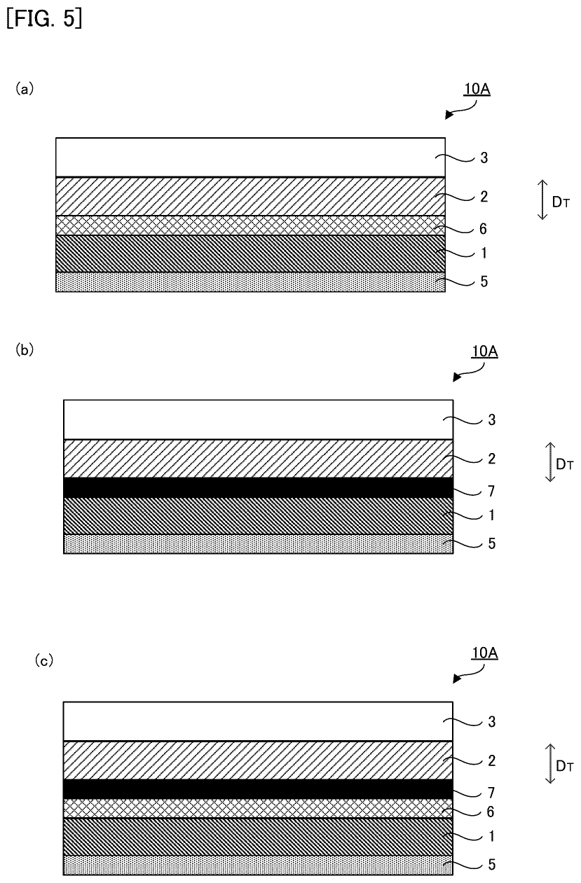

As shown in FIG. 5(a), the stacked body 10A in the present embodiment may include a primer layer 6 between the first layer 1 and second layer 2. The material of the primer layer is not particularly limited as long as it is a material capable of improving the close adhesiveness between the first layer 1 and second layer 2, and examples thereof may include resins. Examples of the resin may include (meth)acrylic resins, urethane resins, (meth)acrylic-urethane copolymers, vinyl chloride-vinyl acetate copolymer resins, polyesters, butyral resins, chlorinated polypropylenes, chlorinated polyethylenes, epoxy resins, and silicone resins. One type of these resins may be used alone, and two types or more may be used in a combination.

The thickness of the primer layer may be the thickness capable of improving the close adhesiveness between the first layer and second layer, and may be, for example, 0.1 μm or more and 10 μm or less, and preferably 0.2 μm or more and 5 μm or less.

Examples of a method for forming a primer layer may include a method wherein the first layer is coated with a composition for a primer layer. Examples of the method for applying may include general coating methods such as a gravure coating method, a gravure reverse coating method, a gravure offset coating method, a spin coating method, a roll coating method, a reverse roll coating method, a blade coating method, a dip coating method, a screen printing method, and a die coating method. Also, a transfer method may also be used as a method for forming a primer layer.

### (4) Decorative Layer

As shown in FIG. 5(b), the stacked body 10A in the present embodiment may include a decorative layer 7 between the first layer 1 and second layer 2. As shown in FIG. 5(c), the stacked body 10A in the present embodiment may include the decorative layer 7 and the primer layer 6. In this case, the decorative layer 7 may be disposed between the primer layer 6 and second layer.

The decorative layer includes a colorant and a binder resin. The binder resin included in the decorative layer is not particularly limited, and the resins used for common decorative layers may be used. Also, the colorant included in the decorative layer is not particularly limited, and known colorants used for common decorative layers can be used.

The decorative layer is usually disposed on a part of the first layer. Also, the decorative layer may have a patterned shape. The thickness of the decorative layer is not particularly limited, and it is, for example, 5 μm or more and 40 μm or less.

### 5. Properties of Stacked Body

### (1) Total Light Transmittance and Haze

The total light transmittance of the stacked body in the present embodiment is preferably, for example, 80% or more, more preferably 85% or more, and further preferably 88% or more. When the total light transmittance is high as described above, the stacked body may have good transparency.

The haze of the stacked body in the present embodiment is preferably, for example, 2.0% or less, more preferably 1.5% or less, and further preferably 1.0% or less. When the haze is low as described above, the stacked body may have good transparency.

Here, the haze of the stacked body may be measured according to JIS K-7136, and may be measure with, for example, a haze meter HM150 from Murakami Color Research Laboratory Co., Ltd.

### (2) Bending Resistance

The stacked body in the present embodiment preferably has a bending resistance. Particularly, when the third layer of the stacked body in the present embodiment is a glass substrate having a thickness of 30 μm, it is preferable that a peeling of the second layer does not occur in the clamshell-type bending test wherein the following cycle is repeated for 200,000 times; in one cycle, a flat stacked body is bent, with a radius of curvature of the bent portion of 1.5 mm, and then, the stacked body is opened so that it is flat again.

Particularly, it is preferable that a peeling of the second layer does not occur when the following cycle is repeated for 200,000 times; in one cycle, a flat stacked body is bent, with a radius of curvature of the bent portion of 1.25 mm, and then, the stacked body is opened so that it is flat again.

Also, when the thickness of the glass substrate is 100 μm, it is preferable that a peeling of the second layer does not occur when the test described above is carried out, setting the radius of curvature of the bent portion to 4 mm.

By the clamshell-type bending test, deformation occurs only in a portion of the stacked body, located between the two plates described below. Therefore, it is possible to evaluate the bending resistance of the stacked body when local bent portion occurs.

### (Clamshell-Type Bending Test)

Using, for example, Desktop Model Endurance Test Machine, Tension-Free (registered trademark) Folding Clamshell-type (from Yuasa System Co., Ltd.), the clamshell-type bending test is carried out as follows. In the Desktop Model Endurance Test Machine, the stacked body is kept by the 2 plates of double-joint clamshell type. When one plate of the two plates is operated by a rotary reciprocation axis, the two plates are opened and closed keeping each angle to each other by the parallel link structure.

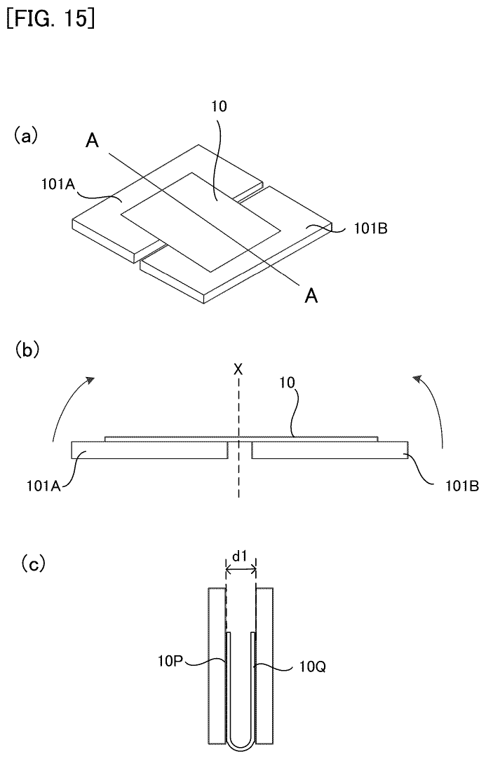

Firstly, a test piece of the stacked body having a size of 20 mm×100 mm, is prepared. Then, as shown in FIG. 15(a) and FIG. 15(b), the sample of the stacked body 10 is fixed flat on the two plates 101A and 101B disposed on the same flat surface. Incidentally, FIG. 15(b) is an A-A line cross-sectional view of FIG. 15(a). Then, as shown in FIG. 15(c), the two plates 101A and 101B are rotated symmetrically with respect to a flat surface X so that the two plates are parallel to and apart from each other with a certain distance between them. Thereby, the stacked body is bent with a predetermined radius of curvature R, between the two plates. Then, one cycle is completed by putting the two plates back to their original condition, and positioning the stacked body on the same flat surface so that the stacked body flattens to the initial condition. When the two plates are apart and parallel, the distance between the two plates is regarded as d1, and d½ substantially corresponds to the radius of curvature R.

In the clamshell-type bending test, the stacked body may be folded so that the first layer of the stacked body is on the inner side, or the stacked body may be folded so that the third layer of the stacked body is on the inner side; and in either of these cases, it is preferable to have the bending resistance described above. In the present embodiment, it is particularly preferable that the stacked body has the bending resistance described above, when the stacked body is folded so that the first layer of the stacked body is on the inner side.

In the stacked body in the present embodiment, it is preferable that a peeling of the second layer does not occur in the following U-shaped bending test.

In the U-shape bending test, the stacked body may be folded so that the first layer of the stacked body is on the inner side, or the stacked body may be folded so that the third layer of the stacked body is on the inner side; and in either of these cases, it is preferable to have the bending resistance described above. In the present embodiment, it is particularly preferable that the stacked body has the bending resistance described above, when the stacked body is folded so that the first layer of the stacked body is on the inner side.

### (U-Shaped Bending Test)

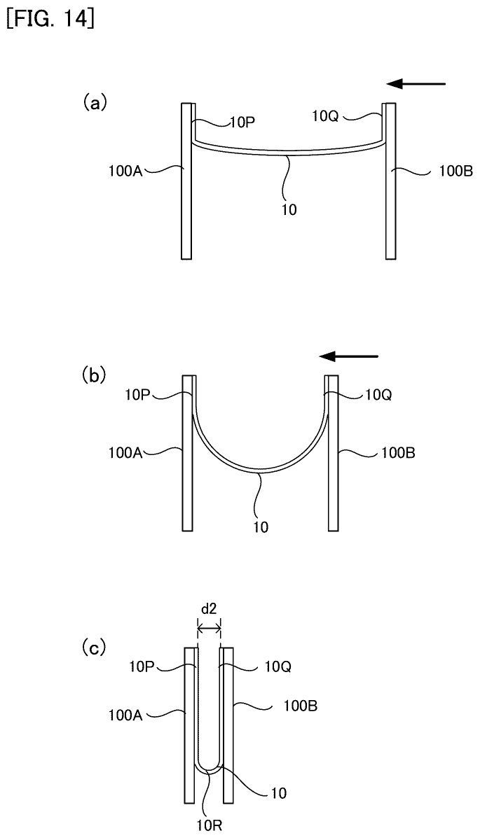

The U-shape bending test is carried out as follows. Firstly, a test piece of a stacked body having a size of 20 mm×100 mm, is prepared. Then, as shown in FIG. 14(a), a short side portion 10P and a short side portion 100 facing the short side portion 10P of the stacked body 10 are respectively fixed by parallelly arranged fixing portions 100A, 100B. As shown in FIG. 14(a), the fixing portion 100B is movable by sliding in horizontal direction. Then, as shown in FIG. 14(b) to (c), by moving the fixing portion 100B so as to be closer to the fixing portion 100 A, the stacked body 10 is bent into a U-shape, and the stacked body is folded into 180° so that the distance “d2” between opposing side portions 10P, 10Q of the stacked body 10 is 3.0 mm. This operation is repeated for 200,000 times.

### (3) Peeling Strength

The peeling strength of the stacked body in the present embodiment is, for example, 5 N/20 mm width or more, may be 6 N/20 mm width or more, and may be 10 N/20 mm width or more. When the peeling strength is the above value or more, the adhesive strength of the second layer is sufficient and the first layer and the third layer are sufficiently joined in the stacked body. That is, in the stacked body in the present embodiment, the peeling strength between the first layer and second layer, as well as the peeling strength between the second layer and third layer is preferably in the above range. Meanwhile, the peeling strength of the stacked body is, for example, 50 N/20 mm width or less, and may be 40 N/20 mm width or less.

Here, the method for measuring the peeling strength of the stacked body in the present embodiment is as follows.

The peeling strength can be measured by a 180° peeling test according to JIS Z0237: 2009. Firstly, a test piece having a width of 20 mm and a length of 100 mm is cut out from the stacked body. Using “Autograph AG-X IN (load cell: SBL-1KN)” from Shimadzu Corporation as a universal tester (tensile tester), the peeling strength is measured by peeling at the interface between the first layer and the third layer, under conditions of at temperature of 25° C., distance between the chucks of the tensile tester of 50 mm, a tensile speed of 300 mm/minute, and a peeling angle of 180°, by a 180° peeling test in accordance with JIS Z0237: 2009.

Incidentally, when the width of the test piece is not 20 mm, the peeling strength (actually measured value) measured by the above 180° peeling test is converted into 20 mm width by the following formula.

Peeling strength [N/20 mm] converted into 20 mm width=actually measured peeling strength value [N/20 mm]×20 [mm]/teat piece width [mm]

### 6. Use Application of Stacked Body

The stacked body in the present embodiment may be used as a member disposed on the observer side than the display panel, that is, a front panel in a display device. The stacked body in the present embodiment may be used for a display device used for an electronic device such as smart phones, tablet terminals, wearable terminals, personal computers, televisions, digital signages, public information displays (PIDs), and car mounted displays.

Among them, the stacked body in the present embodiment may be preferably used for flexible displays such as foldable displays, rollable displays, and bendable displays; and particularly preferably used for the foldable displays.

When the stacked body in the present embodiment is disposed on the surface of a display device, the stacked body may be disposed so that the third layer side surface is on the display panel side and the first layer side surface is on the outer side; and the stacked body may be disposed so that the first layer side surface is on the display panel side and the third layer side surface is on the outer side, and the former is preferable.

The method for disposing the stacked body in the present embodiment on the surface of a display device is not particularly limited, and examples thereof may include a method via an adhesive layer. As an adhesive layer, a known adhesive layer used for adhering a stacked body in a display device may be used.

The stacked body in the present embodiment comprises a first layer, a second layer, and a third layer in this order, wherein a recovery at a cross-section of the second layer, according to a nanoindentation method, is a predetermined value or more.

### A-2. Stacked Body (Second Embodiment)

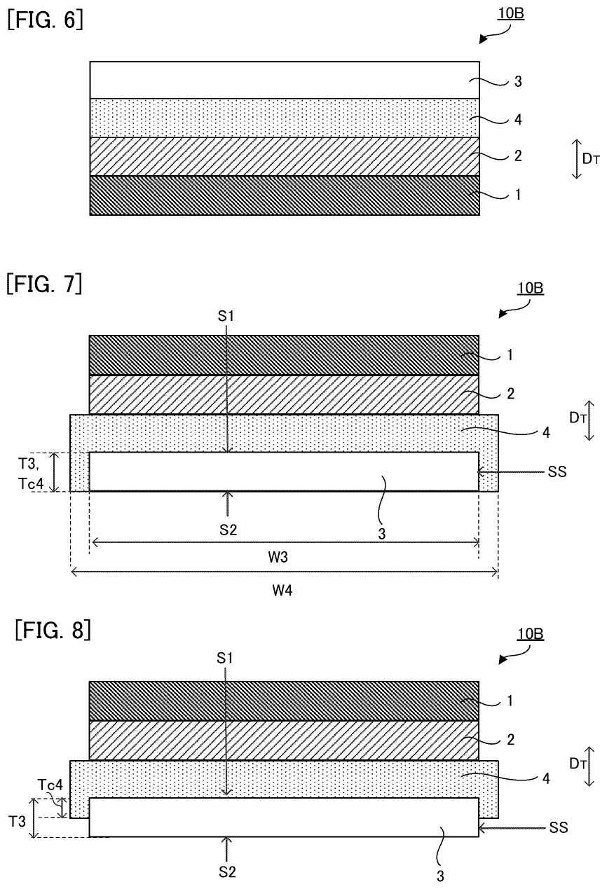

FIG. 6 is a schematic cross-sectional view illustrating an example of a stacked body in the second embodiment in the present disclosure. As shown in FIG. 6, the stacked body 10B in the present embodiment may include a first layer 1, a second layer 2, a fourth layer 4 and a third layer 3, in this order in the thickness direction Dr. In the present disclosure, the recovery at a cross-section of the second layer 2 and the fourth layer 4, according to a nanoindentation method, are respectively a predetermined value or more.

As described above, when used, for example, a foldable display, as for a stacked body including a first layer, a second layer, a fourth layer and a third layer, when the stacked body is locally bent repeatedly, there is a problem that the second layer is peeled off from the first layer, or the third layer is peeled off from the fourth layer. In this phenomenon, the harder the layer (for example, a layer with a high composite elastic modulus), the more prone to be peeled off, since the shear stress concentrated in the bent portion is higher.

However, the inventors of the present disclosure have found out that the likelihood of peeling of the second layer and fourth layer is not dependent on the composite elastic modulus. Further, the inventors of the present disclosure have carried out diligent studies and found that, for the same reasons as described above, by respectively making the recovery at a cross-section of the second layer and fourth layer, according to a nanoindentation method, a predetermined value or more, the peeling of the second layer and the peeling of the fourth layer can be suppressed so as to exhibit excellent bending resistance, even when locally bent.

Also, according to the present embodiment, it was found out that, by disposing a fourth layer between the third layer and second layer, the impact resistance can be improved.

### 1. Second Layer

The second layer in the present embodiment is disposed between the first layer and third layer, and along with the fourth layer, it has a function as a joining layer joining the first layer and third layer. In the present embodiment, the recovery at a cross-section in the thickness direction of the second layer 2, according to a nanoindentation method, is a predetermined value or more.

Other properties of the second layer are similar to the second layer in the first embodiment.

### 2. Fourth Layer

The fourth layer in the present embodiment is disposed between the first layer and third layer, and along with the second layer, it has a function as a joining layer joining the first layer and third layer. Further, it is disposed between the second layer and third layer, and has a function as an impact absorbing layer. By disposing the fourth layer, when an impact is imparted to the stacked body, the impact is absorbed so that the impact resistance may be improved. Also, when the third layer is a glass substrate, the crack of the glass substrate may be suppressed.

In the present embodiment, the recovery at a cross-section in the thickness direction of the fourth layer, according to a nanoindentation method, is a predetermined value or more. The cross-section in the thickness direction of the fourth layer is the cross-sectional surface obtained by cutting the fourth layer in the thickness direction Dr (the stacked direction of the stacked body).

### (1) Recovery According to Nanoindentation Method

The recovery at a cross-section of the fourth layer, according to a nanoindentation method is usually 10% or more, may be 20% or more, may be 30% or more, may be 40% or more, and may be 50% or more. Meanwhile, the recovery is, for example, 80% or less, may be 70% or less, and may be 60% or less.

Specifically, the recovery is preferably in a range of 10% or more and 80% or less, more preferably in a range of 20% or more and 70% or less, and particularly preferably 30% or more and 60% or less.

The method for measuring the recovery at a cross-section of the fourth layer, according to a nanoindentation method is similar to the method for measuring the recovery at a cross-section of the second layer, according to a nanoindentation method in the first embodiment.

### (2) Composite Elastic Modulus

In the present embodiment, the composite elastic modulus of the fourth layer may be, for example, 0.01 GPa or more, preferably 0.05 GPa or more, and more preferably more than 0.05 GPa. Further, it is particularly preferably 3.0 GPa or more. When the composite elastic modulus of the fourth layer is the above value or more, it is preferable to improve the impact resistance of the stacked body. Also, the composite elastic modulus of the fourth layer is, for example, 7.0 GPa or less, may be 6.5 GPa or less, and may be 6.3 GPa or less.

The method for measuring the composite elastic modulus of the fourth layer is similar to the method for measuring the composite elastic modulus of the second layer in the first embodiment.

(3) Indentation Hardness H_{IT}/Composite Elastic Modulus Eᵣ

For the fourth layer in the present embodiment, the ratio (indentation hardness H_{IT}/composite elastic modulus Eᵣ) of the indentation hardness Hir (MPa) with respect to the composite elastic modulus Eᵣ (GPa) is, for example, more than 30, and may be 40 or more. Meanwhile, the ratio is, for example, 85 or less, and may be 70 or less. When indentation hardness Hur/composite elastic modulus Eᵣ is the above value or more, the bending resistance tends to improve. Incidentally, in the case of high hardness materials such as glass having a composite elastic modulus of approximately 70 GPa, brittle fracture tends to occur when the H_{IT}/Eᵣ is high. However, in the region where the composite elastic modulus is several GPa or less, the bending resistance tends to be good when the H_{IT}/Eᵣ is the above value or more.

Incidentally the method for measuring the nanoindentation hardness H_{IT} is similar to the method for measuring the nanoindentation hardness H_{IT} of the second layer in the first embodiment.

### (4) Material

The fourth layer preferably includes a resin. The resin included in the fourth layer is not particularly limited as long as it has transparency and impact absorbing properties, and the fourth layer has the recovery described above. Specific examples of such resin may include polyimide based resins, polyamide based resins, polyester based resins, cellulose based resins, acrylic based resins, polycarbonate based resins, polyethylene naphthalate based resins, urethane based resins, vinyl chloride based resins, vinyl acetate based resins, and epoxy resins. One type of these resins may be used alone, and two types or more may be used in a combination.

Incidentally, in the present descriptions, polyimide based resin refers to a polymer including an imide bond in the main chain. Examples of the polyimide based resin may include polyimide, polyamideimide, polyesterimide, and polyetherimide.

The fourth layer may further include an additive if necessary. Examples of the additive may include adhesive improving agents, inorganic particles, organic particles, ultraviolet absorbers, antioxidants, light stabilizers, and surfactants.

Examples of a method for forming a fourth layer may include a method wherein the third layer is coated with a resin composition. The method for applying is not particularly limited as long as it is capable of applying with a desired thickness, and examples thereof may include a general coating method such as a gravure coating method, a gravure reverse coating method, a gravure offset coating method, a spin coating method, a roll coating method, a reverse roll coating method, a blade coating method, a dip coating method, a spray coating method, a dye coating method, and a screen printing method. Also, the fourth layer can be formed by a transfer method wherein a fourth layer is transferred to a main surface of the third layer; or a method wherein a film-shaped fourth layer is adhered to a main surface of the third layer via an adhesive layer. Also, before forming the fourth layer, the fourth layer side first main surface S1 of the third layer may be subjected to a close adhesiveness improving treatment such as corona treatment. The close adhesiveness improving treatment may be carried out to the side surface SS of the third layer described later.

### (5) Others

The thickness of the fourth layer is preferably, for example, 5 μm or more, further preferably 10 μm or more, and particularly preferably 20 μm or more. Meanwhile, the thickness is preferably 80 μm or less, further preferably 70 μm or less, and particularly preferably 60 μm or less. Specifically, the thickness is preferably in a range of 5 μm or more and 80 μm or less, further preferably in a range of 10 μm or more and 70 μm or less, and particularly in a range of 20 μm or more and 60 μm or less. When the thickness of the fourth layer is too thick, the bending resistance may be deteriorated. Meanwhile, when the thickness of the fourth layer is too thin, the adhesiveness may not be secured so as to be peeled off.

In the present embodiment, the total thickness of the second layer and the thickness of the fourth layer is preferably 100 μm or less, more preferably 75 μm or less, and particularly preferably 50 μm or less.

As shown in FIG. 7 and FIG. 8, the third layer 3 usually includes a first main surface S1 on the fourth layer side, a second main surface S2 opposite to the first main surface S1, and the side surface SS different from the first main surface S1 and the second main surface S2. As shown in FIG. 7 and FIG. 8, when the third layer 3 is a glass substrate, the fourth layer 4 preferably covers the side surface SS of the third layer 3. In this case, the width W4 of the fourth layer 4 is larger than the width W3 of the third layer 3.

When the third layer is a glass substrate, by the fourth layer covering the side surface of the third layer, the strength of the side surface of the glass substrate can be increased. Also, the microcrack on the side surface of the glass substrate can be filled by the fourth layer, and the strength of the side surface of the glass substrate can be increased. Therefore, the impact resistance of the edge portion of the glass stacked body can be increased.

Also, the degree of coverage of the side surface of the third layer by the fourth layer is not particularly limited as long as the strength of the side surface of the third layer can be increased by covering the side surface of the third layer by the fourth layer. For example, the entire surface of the side surface of the third layer may be covered by the fourth layer, and a part of the side surface of the third layer may be covered by the fourth layer. Specifically, in FIG. 7, the fourth layer 4 covers the entire surface of the side surface of the third layer 3. Meanwhile, in FIG. 8, the fourth layer 4 covers a part of the side surface of the third layer 3.

As for the degree of coverage of the side surface of the third layer by the fourth layer, in the thickness direction Dr, specifically, the ratio (Tc4/T3) of the thickness Tc4 of the side surface of the third layer covered by the fourth layer, with respect to the thickness T3 of the third layer is, for example, 0.5 or more, may be 0.6 or more, and may be 0.7 or more. Meanwhile, the ratio is, for example, 1.0 or less, may be 0.9 or less, and may be 0.8 or less. Specifically, the above ratio (Tc4/T3) is, for example, 0.5 or more and 1.0 or less, may be 0.6 or more and 0.9 or less, and may be 0.7 or more and 0.8 or less. When the ratio is in the above range, the impact resistance of the side surface of the glass substrate is improved.

The shape of the glass substrate is usually a cuboid, and it is a hexahedron. Also, even when the glass substrate is beveled, for example, the shape of the glass substrate can be considered to be usually cuboid and roughly hexahedron. In this case, the glass substrate includes facing first surface and second surface, and four side surfaces. In such cases, as for the degree of coverage of the side surface of the glass substrate by the second layer, at least one side surface out of the four side surfaces of the glass substrate has only to be covered by the second layer. That is, in this case, one side surface out of the four side surfaces of the glass substrate may be covered by the fourth layer; two side surfaces may be covered by the fourth layer; three side surfaces may be covered by the fourth layer; and four side surfaces may be covered by the fourth layer.

Among them, facing two side surfaces out of the four side surfaces of the glass substrate are preferably covered by the fourth layer; and two side surfaces approximately parallel to the bending direction of the glass stacked body, out of the four side surfaces of the glass substrate, are preferably covered by the second layer. The reason therefor is to suppress cracking in the bent portion when the glass stacked body is bent, and to improve the bending resistance.

### 3. First Layer

The details of the first layer are similar to the contents of the first layer in the first embodiment.

### 4. Third Layer

The details of the third layer are similar to the contents of the third layer in the first embodiment.

### 5. Other Layers

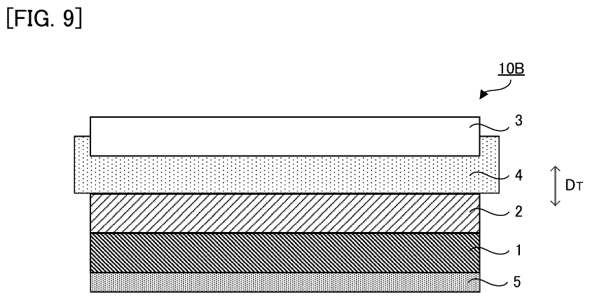

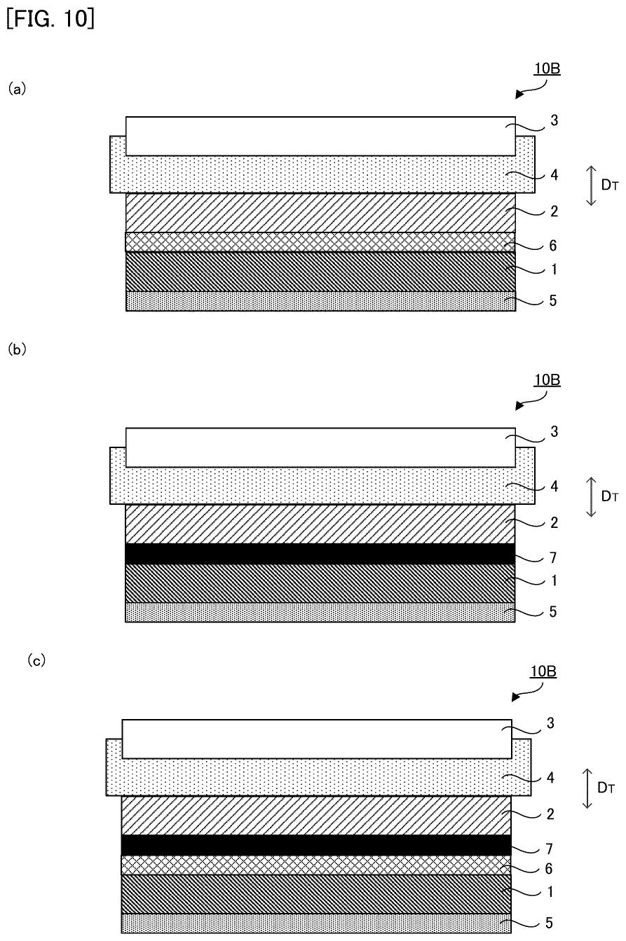

The stacked body in the present embodiment may include another layer, in addition to the first layer, second layer, fourth layer, and third layer described above. The member for a display device in the present embodiment may further include a functional layer on the surface of the first layer that is opposite side to the third layer, or between the first layer and second layer. Examples of the functional layer, disposed on the surface of the first layer that is opposite side to the third layer, may include a hard coating layer, a protective layer, an antireflection layer, and an antiglare layer. Examples of the functional layer, disposed between the first layer and second layer, may include a decorative layer, and a primer layer. As shown in FIG. 9 for example, the stacked body in the present embodiment preferably further includes a hard coating layer 5 on the surface of the first layer 1 that is opposite side to the third layer 3. As shown in FIG. 10(a), the stacked body in the present embodiment may include a primer layer 6 between the first layer 1 and second layer 2. As shown in FIG. 10(b), the stacked body in the present embodiment may include a decorative layer 7 between the first layer 1 and second layer 2. As shown in FIG. 10(c), the stacked body in the present embodiment may include the decorative layer 7 and the primer layer 6 between the first layer 1 and second layer 2. In this case, the decorative layer 7 may be disposed between the primer layer 6 and second layer 2.

The details of these other layers are similar to the detailed contents described in the first embodiment.

### 6. Properties of Stacked Body

### (1) Total Light Transmittance and Haze

The total light transmittance and haze of the stacked body in the present embodiment are similar to the total light transmittance and haze of the stacked body in the first embodiment.

### (2) Bending Resistance

The stacked body in the present embodiment preferably has a bending resistance. Particularly, in the stacked body in the present embodiment, it is preferable that a peeling of the second layer from the first layer, and the peeling of the fourth layer from the third layer do not occur in the clamshell-type bending test and U-shaped bending test described above.

### (3) Peeling Strength

For the stacked film in the present embodiment, it is preferable that the evaluation result of close adhesiveness between the third layer and fourth layer, carried out by the cross-cut method according to JIS K 5600-5-6:1999, is 1 point or less.

The outline of the evaluation of the close adhesiveness strength between the third layer and fourth layer by the cross-cut method is as follows. Firstly, an evaluation sample constituted from the third layer and fourth layer is obtained. The fourth layer of the evaluation sample is cut through with a cutter knife, for example, to form a plurality of right-angle grating patterns. In this case, it is preferable to use a cross-cutting jig that can form the plurality of right-angle grating patterns successively and neatly. Then, an adhesive tape including a pressure-sensitive adhesive layer on one surface, such as a cellophane tape for adhesion, is adhered to cover the entire grating formed above. Then, the edge of the adhered adhesive tape is grasped with a finger, peeled off from the fourth layer, the condition of the peeling of the fourth layer is visually observed, and the results are classified according to the following evaluation criteria. The points for each classification are: 0 point for classification 0, 1 point for classification 1, 2 points for classification 2, 3 points for classification 3, 4 points for classification 4, and 5 points for classification 5. Here, the size of one side of the grating pattern is 2 mm. Incidentally, in order to properly contact the adhesive tape to the fourth layer, the adhesive tape is rubbed tightly with a fingertip. The entire area is visually checked to confirm that the tape is properly adhered. The tape is peeled off within 5 minutes after adhering thereof, and the edge of the tape is grasped at an angle as close to 60° as possible, and the tape is securely pulled off approximately within 0.5 seconds or more and 1.0 second or less.
Classification 0: the cutting edge is perfectly smooth, with no peeling in the mesh of any grid.
Classification 1: there is a small peeling of the coating film at the intersection of the cuts. However, the impact on the cross-cut portion does not clearly exceed 5%.
Classification 2: the coating film is peeled along the cutting edge and/or at the intersection. The impact on the cross-cut portion clearly exceeds 5%, but does not exceed 15%.
Classification 3: the coating film is partially or entirely peeled largely along the cutting edge and/or various parts of the grid are partially or entirely peeled. The impact on the cross-cut portion clearly exceeds 15%, but does not exceed 35%.
Classification 4: the coating film is partially or entirely peeled largely along the cutting edge and/or several parts of the grid are partially or entirely peeled. The impact on the cross-cut portion does not clearly exceed 65%.
Classification 5: any one of degrees of the peeling which cannot be classified by the classification 4.

In the stacked body in the present embodiment, the peeling strength between the fourth layer and second layer is, for example, 5 N/20 mm width or more, may be 6 N/20 mm width or more, and may be 10 N/20 mm width or more. When the peeling strength is the above value or more, the adhesive strength of the second layer is sufficient and the second layer and the fourth layer are sufficiently joined in the stacked body. Meanwhile, the peeling strength of the stacked body is, for example, 50 N/20 mm width or less, and may be 40 N/20 mm width or less.

Here, the method for measuring the peeling strength of the stacked body in the present disclosure is as follows.

The peeling strength can be measured by a 180° peeling test according to JIS Z0237: 2009. Firstly, a test piece having a width of 20 mm and a length of 100 mm is cut out from the stacked body. Using “Autograph AG-X IN (load cell: SBL-1KN)” from Shimadzu Corporation as a universal tester (tensile tester), the peeling strength is measured by peeling at the interface between the second layer and the fourth layer, under conditions of at a temperature of 25° C., a distance between the chucks of the tensile tester of 50 mm, a tensile speed of 300 mm/minute, and a peeling angle of 180°, by a 180° peeling test in accordance with JIS Z0237: 2009.

Incidentally, when the width of the test piece is not 20 mm, the peeling strength (actually measured value) measured by the above 180 peeling test is converted into 20 mm width by the following formula.

Peeling strength [N/20 mm] converted into 20 mm width=actually measured peeling strength [N/20 mm]×20 [mm]/teat piece width [mm]

### 7. Use Application of Stacked Body

The use applications of the stacked body in the present embodiment are similar to the use applications of the stacked body in the first embodiment.

### B. Display Device

The display device in the present disclosure comprises: a display panel, and the stacked body described above disposed on an observer side of the display panel.

FIG. 11 is a schematic cross-sectional view exemplifying a display device in the present disclosure, and it is an example provided with the stacked body described above. As shown in FIG. 11, display device 20 comprises display panel 21, and the stacked body 10 (stacked body 10A in the first embodiment, or stacked body 10B in the second embodiment) disposed on an observer side of the display panel 21. In the display device 20, the stacked body 10 is used as a member to be disposed on the front surface of the display device 20, and an adhesive layer 22 is disposed between the stacked body 10 and the display panel 21.

The stacked body in the present disclosure may be similar to the stacked body described above.

Examples of the display panel in the present disclosure may include a display panel used for a display device such as a liquid crystal display device, an organic EL display device, and a LED display device.

The display device in the present disclosure may include a touch-sensitive panel member between the display panel and the stacked body.

The display device in the present disclosure is preferably a flexible display. Among them, the display device in the present disclosure is preferably foldable. That is, the display device in the present disclosure is more preferably a foldable display. Since the display device in the present disclosure includes the stacked body described above, it has excellent impact resistance and bending resistance, and is suitable as a flexible display, and further a foldable display.

### C. Member for Stacked Body

The member for a stacked body in the present disclosure is a member for a stacked body used for the stacked body described in “A-1. Stacked body (first embodiment)” or “A-2. Stacked body (second embodiment)”, wherein the first layer and second layer in “A-1. Stacked body (first embodiment)” or “A-2. Stacked body (second embodiment)” are stacked.

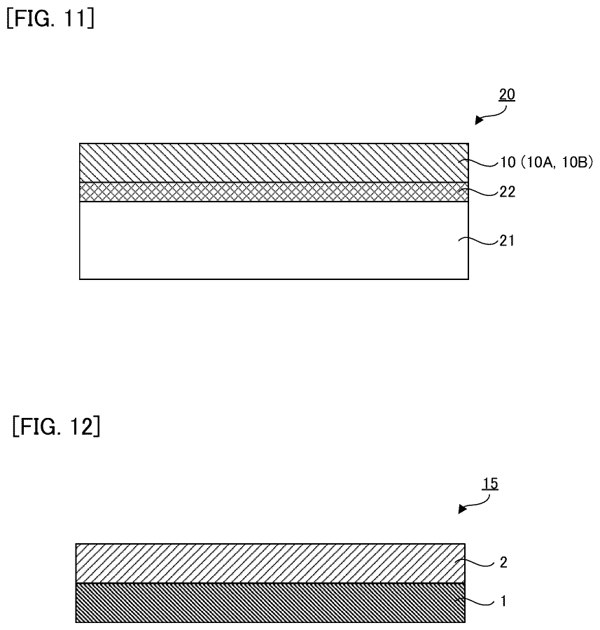

FIG. 12 is a schematic cross-sectional of a member for a stacked body in the present disclosure. The member for a stacked body 15 shown in FIG. 12 comprises a first layer 1 and a second layer 2, and the recovery at a cross-section of the second layer 2, according to a nanoindentation method, is 10% or more. As shown in FIG. 1 for example, such member for a stacked body 15 is used for producing a stacked body 10A including the first layer 1, the second layer 2, and the third layer 3 in this order. Alternatively, as shown in FIG. 6 for example, such member for a stacked body 15 is used for producing a stacked body 10B including the first layer 1, the second layer 2, the fourth layer 4, and the third layer 3 in this order.

The stacked body 10A described above is produced by closely adhering the second layer side surface of the member for a stacked body in the present disclosure to a glass substrate or a resin substrate to be the third layer. Also, the stacked body 10B described above is produced by closely adhering the second layer side surface of the member for a stacked body (first member for a stacked body) in the present disclosure to the fourth layer side surface of a second member for a stacked body including the fourth layer and third layer. According to such a member for a stacked body, for the reasons described above, a stacked body with good bending resistance can be obtained.

The first layer, second layer, third layer and fourth layer are similar to the first layer, second layer, third layer and fourth layer in “A-1. Stacked body (first embodiment)” and “A-2. Stacked body (second embodiment)” described above.

Incidentally, the present disclosure is not limited to the embodiments. The embodiments are exemplification, and any other variations are intended to be included in the technical scope of the present disclosure if they have substantially the same constitution as the technical idea described in the claim of the present disclosure and offer similar operation and effect thereto.

### EXAMPLES

The present disclosure is hereinafter explained in further details with reference to Examples and Comparative Examples.

### I. First Embodiment

### Comparative Example

### (Production of Member for a Stacked Body)

Firstly, a pet film having a thickness of 50 μm was prepared as the first layer. One surface of the PET film was coated with the following curable resin composition for a hard coating layer so as to be a predetermined thickness, dried at 80° C. for 3 minutes, and then cured by ultraviolet irradiation to form a hard coating layer having a thickness of 10 μm.

The curable resin composition for a hard coating layer was prepared by compounding each component so as to be the composition shown below.
Mixture of dipentaerythritol pentaacrylate and dipentaerythritol hexaacrylate (M403 from Toagosei Co., Ltd.): 25 parts by mass
Dipentaerythritol EO modified hexaacrylate (A-DPH-6E from Shin-Nakamura Chemical Co., Ltd.): 25 parts by mass
Deformed silica fine particle (average particle size: 25 nm, from JGC Catalysts and Chemicals Ltd.): 50 parts by mass (in terms of solid).
Photopolymerization initiator (Irg184): 4 parts by mass
Fluorine based leveling agent (F568 from DIC Corporation): 0.2 parts by mass (in terms of solid)
Ultraviolet absorber 1 (DAINSORB P6, from Daiwa Kasei Co., Ltd.) 3 parts by mass
Solvent (MIBK): 150 parts by mass

Then, another surface of the PET film was coated with the composition for a second layer A, and dried to form a joining layer A (second layer) having a thickness of 5 μm. Thus, a member for a stacked body including a first layer and a second layer was obtained. Then, the second layer side surface of the member for a stacked body was closely adhered to a glass substrate (chemically strengthened glass, thickness of 30 μm), thermally fusion bonded, and then aged to form a stacked body including the first layer, second layer, and third layer.

The composition for a second layer A was prepared by compounding each component so as to be the composition shown below.

### (Composition for Second Layer A)

Amorphous polyester based resin (Mw of 16,000, Tg of 7° C., tensile elongation at break of 1%): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-1

A stacked body was produced in the same manner as in Comparative Example except that a joining layer B (second layer) was formed using the composition for a second layer B, instead of the composition for a second layer A.

The composition for a second layer B was prepared by compounding each component so as to be the composition shown below.

### (Composition for Second Layer B)

Polyether urethane based resin: (Tg of −45° C.), 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-2

A stacked body was produced in the same manner as in Comparative Example except that a joining layer C (second layer) was formed using the composition for a second layer C, instead of the composition for a second layer A.

The composition for a second layer C was prepared by compounding each component so as to be the composition shown below.

### (Composition for Second Layer C)

Amorphous polyester based resin (Mw of 16,000, Tg of 65° C., tensile elongation at break of 3%): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-3

A stacked body was produced in the same manner as in Comparative Example except that a joining layer D (second layer) was formed using the composition for a second layer D, instead of the composition for a second layer A.

The composition for a second layer D was prepared by compounding each component so as to be the composition shown below.

### (Composition for Second Layer D)

Amorphous polyester based resin (Mw of 16,000, Tg of 20° C., tensile elongation at break of 1100%): 100 parts by mass.
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-4

A stacked body was produced in the same manner as in Comparative Example except that a joining layer E (second layer) was formed using the composition for a second layer E, instead of the composition for a second layer A.

The composition for a second layer E was prepared by compounding each component so as to be the composition shown below.

### (Composition for Second Layer E)

Amorphous polyester based resin (Tg of 1° C., tensile elongation at break of 1000%): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-5

A stacked body was produced in the same manner as in Comparative Example except that a joining layer F (second layer) was formed using the composition for a second layer F, instead of the composition for a second layer A.

The composition for a second layer F was prepared by compounding each component so as to be the composition shown below.

### (Composition for Second Layer F)

Amorphous polyester based resin (Mw of 16,000, Tg of 40° C., tensile elongation at break of 3%): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-6

A stacked body was produced in the same manner as in Comparative Example except that a joining layer G (second layer) was formed using the composition for a second layer G, instead of the composition for a second layer A.

The composition for a second layer G was prepared by compounding each component so as to be the composition shown below.

### (Composition for Second Layer G)

Modified polyolefin resin (Tg of 0° C. or less): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-7

A stacked body was produced in the same manner as in Comparative Example except that a joining layer H (second layer) was formed using the composition for a second layer H, instead of the composition for a second layer A.

The composition for a second layer H was prepared by compounding each component so as to be the composition shown below.

### (Composition for Second Layer H)

Polyester based resin (Tg of 70° C., tensile elongation at break of 2%): 100 parts by mass
Hexamethylene diisocyanate (Coronate 2203 from Tosoh Corporation): 5 parts by mass
Silane coupling agent (KBM-403 from Shin-Etsu Chemical Co., Ltd.): 5 parts by mass
Fluorine based leveling agent (F568, DIC Corporation): 0.2 parts by mass
Solvent (MEK): 310 parts by mass
Solvent (toluene): 310 parts by mass

### Example 1-8

A stacked body was produced in the same manner as in Comparative Examples, except that the joining layer I was formed by adhering a joining layer having a thickness of 50 μm (acrylic based pressure-sensitive adhesive sheet, OCA, Tg of −9° C.) (“8146-2” from 3M Japan Limited), as the second layer, using a hand roller.

### Example 1-9

A stacked body was produced in the same manner as in Comparative Examples, except that the joining layer J was formed by adhering a joining layer having a thickness of 10 μm (acrylic based pressure-sensitive adhesive sheet, OCA, Tg of −8° C.) (“Panaclean PD-S1” from Panac Co., Ltd.), as the second layer, using a hand roller.

### Example 1-10

A stacked body was produced in the same manner as in Comparative Example except that a joining layer K (second layer) was formed using the composition for a second layer K, instead of the composition for a second layer A.

The composition for a second layer K was prepared by compounding each component so as to be the composition shown below.

### (Composition for Second Layer K)

Polyester urethane based resin (UR-8300, solid content of 30%, from Toyobo Co., Ltd.): 100 parts by mass
Hexane methylene diisocyanate (Coronate 2203 from Tosoh Corporation): 1.5 parts by mass
Silane coupling agent (KBM-403 from Shin-Etsu Chemical Co., Ltd.): 1.5 parts by mass
Fluorine based leveling agent (F568 from DIC Corporation): 0.2 parts by mass (in terms of solid)
Solvent (MEK): 58 parts by mass
Solvent (toluene): 58 parts by mass

### Example 1-11

A stacked body was produced in the same manner as in Comparative Example except that a joining layer L (second layer) was formed using the composition for a second layer L, instead of the composition for a second layer A.

The composition for a second layer L was prepared by compounding each component so as to be the composition shown below.

### (Composition for Second Layer L).

Polyester urethane based resin (UR-5537, solid content of 30%, from Toyobo Co., Ltd.): 100 parts by mass
Hexane methylene diisocyanate (Coronate 2203 from Tosoh Corporation): 1.5 parts by mass
Silane coupling agent (KBM-403 from Shin-Etsu Chemical Co., Ltd.): 1.5 parts by mass
Fluorine based leveling agent (F568 from DIC Corporation): 0.2 parts by mass (in terms of solid)
Solvent (MEK): 58 parts by mass
Solvent (toluene): 58 parts by mass

### Example 1-12

A stacked body was produced in the same manner as in Comparative Example except that a joining layer D (second layer) was formed, so as to cover side surface of the third layer, using the composition for a second layer D described above, instead of the composition for a second layer A. On this occasion, the ratio (Tc2/T3) of the thickness Tc2 of the side surface of the third layer covered by the second layer, with respect to the thickness T3 of the third layer, was 0.7.

### (1) Measurement of Recovery

For the obtained stacked body, the recovery at the cross-section of the second layer was measured by the method for measuring a recovery according to the nanoindentation method described above. The results are shown in Table 1.

### (2) Measurement of Composite Elastic Modulus

For the obtained stacked body, the composite elastic modulus at the cross-section of the second layer was measured by the method for measuring a composite elastic modulus at the cross-section of the second layer described above. The results are shown in Table 1.

(3) Indentation Hardness H_{IT}/Composite Elastic Modulus Eᵣ

For the obtained stacked body, the indentation hardness H_{IT} (MPa) at the cross-section of the second layer was measured by the method for measuring indentation hardness H_{IT} at the cross-section of the second layer described above, and the ratio (indentation hardness H_{IT}/composite elastic modulus Eᵣ) of the indentation hardness Hur with respect to the composite elastic modulus Eᵣ (GPa) was calculated. The results are shown in Table 1.

### [Evaluation]

### (1) Clamshell-Type Bending Test (CS Bending Test)

For the obtained stacked body, a dynamic bending test was carried out by the clamshell-type bending test described above. The existence of the peel of the second layer of the stacked body, when the stacked body was repeatedly bent with a radius of curvature of R for 200,000 times, was confirmed and evaluated according to the following criteria. In this case, the stacked body was bent so that the hard coating layer was on the inner side, and the glass substrate was on the outer side.

### Evaluation Criteria

A: no change after 200,000 bends at R of 1.25 mm
B: no change after 200,000 bends at R of 1.5 mm
C: no change after 200,000 bends at R of 2.0 mm
D: a peel of the second layer occurred after 200,000 bends at R of 2.0 mm

### (2) U-Shaped Bending Test

For the obtained stacked body, a dynamic bending test was carried out by the U-shaped bending test described above, and the bending resistance of the stacked body was evaluated. In this case, the stacked body was bent so that the hard coating layer was on the inner side, and the glass substrate was on the outer side, and the radius of curvature R was 1.5 mm. The results of the dynamic bending test were evaluated based on the following criteria.
A: no change after 200,000 bends at R of 1.5 mm
D: a peel of the second layer occurred after 200,000 bends at R of 1.5 mm

### (3) Measurement of Peeling Strength

For the obtained stacked body, the peeling strength was measured by the method described above. The results are shown in Table 1.

### (4) Edge Portion Impact Test

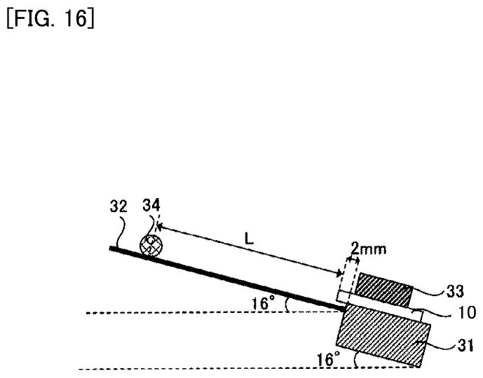

For the obtained stacked body, the impact test as shown in FIG. 16 was carried out. Firstly, the sample table 31 and rail 32 were arranged at an angle of 16° inclined to the horizontal surface. Then, the stacked body 10 was disposed on the sample table 31, and a weight 33 was disposed on the stacked body 10 to fix the stacked body 10. At this time, the stacked body 10 was fixed so that the edge portion of the stacked body 10 protruded 2 mm from the side surface of the sample table 31. Then, a steel ball 34 of 5.5 g, φ11 mm, was dropped, from a predetermined distance L, along the rail 32 to hit the side surface of the stacked body 10. Then, at the edge portion of the stacked body 10, the maximum distance L at which no cracking or fracture occurred in the stacked body 10 was measured, and evaluated according to the following evaluation criteria. Incidentally, the higher the value, the higher the impact resistance.
A: 30 cm or more
B: less than 30 cm

TABLE 1

| | | | 2^{nd} layer | | | | | | | |
|---|---|---|---|---|---|---|---|---|---|---|
| | | | composite | | | | U- | | | |
| | Joining | 2^{nd} layer | elastic | 2^{nd} layer | 2^{nd} layer | CS | shaped | Peeling | | Edge |
| | layer | recovery | modulus | thickness | HIT/Er | Bending | bending | strength | | portion |
| | (2^{nd} layer) | [%] | Er [GPa] | [μm] | [MPa/GPa] | test | Test | [N/20 mm] | Tc2/T3 | impact |
| Comp. Ex. | A | 8.0 | 0.12 | 5 | 30 | D | A | 25.3 | — | B |
| Ex. 1-1 | B | 52.2 | 0.42 | 5 | 84 | A | A | 6.9 | — | B |
| Ex. 1-2 | C | 34.5 | 5.06 | 5 | 51 | A | A | 30 or more | — | B |
| Ex. 1-3 | D | 32.9 | 0.08 | 5 | 36 | A | A | 18 | — | B |
| Ex. 1-4 | E | 23.3 | 2.07 | 5 | 30 | B | A | 11 | — | B |
| Ex. 1-5 | F | 13.3 | 2.95 | 5 | 16 | C | A | 30 or more | — | B |
| Ex. 1-6 | G | 46.2 | 0.27 | 5 | 69 | A | A | 12.4 | — | B |
| Ex. 1-7 | H | 44.2 | 6.08 | 5 | 58 | A | A | 30 or more | — | B |
| Ex. 1-8 | I | 52.3 | 0.01 | 50 | 135 | A | A | 6.7 | — | B |
| Ex. 1-9 | J | 32.2 | 0.01 | 10 | 73 | A | A | 6.5 | — | B |
| Ex. 1-10 | K | 16.6 | 3.35 | 5 | 19 | B | A | 30 or more | — | B |
| Ex. 1-11 | L | 15.5 | 2.36 | 5 | 32 | B | A | 30 or more | — | B |
| Ex. 1-12 | D | 32.9 | 0.08 | 5 | 36 | A | A | 18 | 0.7 | A |

As shown in Table 1, in Example 1-1 to Example 1-12 where the recovery at a cross-section of the second layer, according to a nanoindentation method, was 10% or more, it was confirmed that the bending resistance was good in both the U-shape bending test and the clamshell-type bending test. Meanwhile, in Comparative Example where the recovery at a cross-section of the second layer, according to a nanoindentation method, was less than 10%, it was confirmed that the bending resistance was not sufficient in the clamshell-type bending test. Also, comparing Example 1-3 and Comparative Example, it was confirmed that, although they have similar composite elastic modulus, the evaluation results of the clamshell-type bending test were different. Comparing Example 1-12 and Example 1-3, Example 1-12, wherein the side surface of the third layer was covered by the second layer, showed good edge portion impact resistance.

### Second Embodiment

### Example 2-1

### (Production of Member for a Stacked Body)

Firstly, a pet film having a thickness of 50 μm was prepared as the first layer. One surface of the PET film was coated with the curable resin composition for a hard coating layer so as to be a predetermined thickness, dried at 80° C. for 3 minutes, and then cured by ultraviolet irradiation to form a hard coating layer having a thickness of 10 μm.

Then, another surface of the PET film was coated with the composition for a second layer D described above, and dried to form a joining layer D (second layer) having a thickness of 5 μm. Thus, a member for a stacked body (first member for a stacked body) including a first layer and a second layer was obtained.

Then, a fourth layer having a thickness of 5 μm was formed by coating a glass substrate (chemically strengthened glass, thickness of 30 μm) as the third layer with the following resin composition for a fourth layer so as to cover one main surface and a side surface of the third layer. On this occasion, the ratio (Tc4/T3) of the thickness Tc4 of the side surface of the third layer covered by the fourth layer with respect to the thickness T3 of the third layer was 0.3. Thus, a second member for a stacked body was obtained. Incidentally, the glass substrate as the third layer was subjected to a corona treatment (100 W, 3 mm/minute) as a pretreatment.

### (Resin Composition for Fourth Layer).

Polyester urethane based resin (UR-5537, solid content of 30%, from Toyobo Co., Ltd.): 50 parts by mass
Mixture of dipentaerythritol pentaacrylate and dipentaerythritol hexaacrylate (M403 from Toagosei Co., Ltd.): 50 parts by mass
Omnirad184: 4 parts by mass
Silane coupling agent (KBM-403 from Shin-Etsu Chemical Co., Ltd.): 1.5 parts by mass
Fluorine based leveling agent (F568 from DIC Corporation): 0.2 parts by mass (in terms of solid)
Solvent (MEK): 58 parts by mass
Solvent (toluene): 58 parts by mass

Then, the second layer side surface of the first member for a stacked body was closely adhered to the fourth layer side surface of the second member for a stacked body, thermally fusion bonded, and then aged to form a stacked body including the first layer, second layer, fourth layer, and third layer.

### Example 2-2

A stacked body was produced in the same manner as in Example 2-1, except that the ratio (Tc4/T3) of the thickness Tc4 of the side surface of the third layer covered by the fourth layer with respect to the thickness T3 of the third layer was set to 0.9.

### Example 2-3

A stacked body was produced in the same manner as in Example 2-1, except that the thickness of the fourth layer was 25 μm, and that the ratio (Tc4/T3) of the thickness Tc4 of the side surface of the third layer covered by the fourth layer with respect to the thickness T3 of the third layer was set to 0.7.

### Example 2-4

A stacked body was produced in the same manner as in Example 2-1, except that the thickness of the fourth layer was 50 μm, and that the ratio (Tc4/T3) of the thickness Tc4 of the side surface of the third layer covered by the fourth layer with respect to the thickness T3 of the third layer was set to 0.6.

For the obtained stacked body, (1) Clamshell-type bending test (CS bending test), (2) U-shaped bending test, (3) Measurement of peeling strength, and (4) Edge portion impact test described above were carried out. The results are shown in Table 2.

TABLE 2

| | | | 2^{nd} layer | | | 4^{th} layer |
|---|---|---|---|---|---|---|
| | | | composite | | | composite |
| | Joining | 2^{nd} layer | elastic | 2^{nd} layer | 4^{th} layer | elastic |
| | layer | recovery | modulus | thickness | recovery | modulus |
| | (2^{nd} layer) | [%] | Er [GPa] | [μm] | [%] | Er [GPa] |
| Ex. 2-1 | D | 32.9 | 0.08 | 5 | 50.0 | 5.5 |
| Ex. 2-2 | D | 32.9 | 0.08 | 5 | 50.0 | 5.5 |
| Ex. 2-3 | D | 32.9 | 0.08 | 5 | 50.0 | 5.5 |
| Ex. 2-4 | D | 32.9 | 0.08 | 5 | 50.0 | 5.5 |

| | | | | U- | | | |
|---|---|---|---|---|---|---|---|
| | 4^{th} layer | 2^{nd} layer | CS | shaped | Peeling | | Edge |
| | thickness | HIT/Er | Bending | bending | strength | | portion |
| | [μm] | [MPa/GPa] | test | Test | [N/20 mm] | Tc4/T3 | impact |
| Ex. 2-1 | 5 | 36 | A | A | 21 | 0.3 | B |
| Ex. 2-2 | 5 | 36 | A | A | 21 | 0.9 | A |
| Ex. 2-3 | 25 | 36 | A | A | 22 | 0.7 | A |
| Ex. 2-4 | 50 | 36 | A | A | 23 | 0.6 | A |

As shown in Table 2, in Example 2-1 to Example 2-4 where the recovery at a cross-section of the second layer and fourth layer, according to a nanoindentation method, were respectively 10% or more, it was confirmed that the bending resistance was good in both the U-shape bending test and the clamshell-type bending test. Further, it was confirmed that Example 2-2 to Example 2-4 where (Tc4/T3) was 0.5 or more, exhibited better edge portion impact resistance with respect to Example 2-1.

That is, in the present disclosure, the following inventions can be provided.

[1]

A stacked body comprising a first layer, a second layer, and a third layer in this order, wherein
a recovery at a cross-section of the second layer, according to a nanoindentation method, is 10% or more.
   [2]

The stacked body according to [1], wherein a composite elastic modulus of the second layer is more than 0.05 GPa.

[3]

The stacked body according to [1] or [2], wherein a thickness of the second layer is 1 μm or more and 25 μm or less.

[4]

The stacked body according to any one of [1] to [3], wherein the third layer is a glass substrate having a thickness in a range of 15 μm or more and 115 μm or less.

[5]

The stacked body according to any one of [1] to [4], wherein the first layer is a resin film.

[6]

The stacked body according to any one of [1] to [5], wherein a hard coating layer is included on a surface of the first layer that is opposite side to the second layer.

[7]

The stacked body according to any one of [1] to [6], wherein the stacked body is used as a front panel of a display device.

[8]

A stacked body comprising a first layer, a second layer, a fourth layer, and a third layer in this order, wherein
a recovery at a cross-section of the second layer and the fourth layer, according to a nanoindentation method, is respectively 10% or more.
   [9]

The stacked body according to [8], wherein the third layer includes a first main surface located on a fourth layer side, a second main surface opposite to the first main surface, and a side surface different from the first main surface and the second main surface; and
the fourth layer covers the side surface of the third layer.
   [10]

The stacked body according to [9], wherein a ratio of a thickness of the side surface covered by the fourth layer, with respect to a thickness of the third layer, is 0.5 or more and 1.0 or less.

[11]

The stacked body according to any one of [8] to [10], wherein a composite elastic modulus of the second layer is more than 0.05 GPa.

[12]

The stacked body according to any one of [8] to [11], wherein a composite elastic modulus of the fourth layer is more than 0.05 GPa.

[13]

The stacked body according to any one of [8] to [12], wherein a thickness of the second layer is 1 μm or more and 25 μm or less.

[14]

The stacked body according to any one of [8] to [13], wherein a thickness of the fourth layer is 5 μm or more and 80 μm or less.

[15]

The stacked body according to any one of [8] to [14], wherein the third layer is a glass substrate having a thickness in a range of 15 μm or more and 115 μm or less.

[16]

The stacked body according to any one of [8] to [15], wherein the first layer is a resin film.

[17]

The stacked body according to any one of [8] to [16], wherein a hard coating layer is included on a surface of the first layer that is opposite side to the second layer.

[18]

The stacked body according to any one of [8] to [17], wherein the stacked body is used as a front panel of a display device.

[19]

A display device comprising:
a display panel, and
the stacked body according to any one of [1] to disposed on an observer side of the display panel.
   [20]

A member for a stacked body used for the stacked body according to any one of [1] to [18], wherein
the first layer and the second layer are stacked.

### REFERENCE SIGNS LIST

1: first layer
2: second layer
3: third layer
4: fourth layer
5: hard coating layer
6: primer layer
7: decorative layer
10: stacked body
20: display device
21: display panel

1. A stacked body comprising a first layer, a second layer, and a third layer in this order, wherein
a recovery at a cross-section of the second layer, according to a nanoindentation method, is 10% or more.

2. The stacked body according to claim 1, wherein a composite elastic modulus of the second layer is more than 0.05 GPa.

3. The stacked body according to claim 1, wherein a thickness of the second layer is 1 μm or more and 25 μm or less.

4. The stacked body according to claim 1, wherein the third layer is a glass substrate having a thickness in a range of 15 μm or more and 115 μm or less.

5. The stacked body according to claim 1, wherein the first layer is a resin film.

6. The stacked body according to claim 1, wherein a hard coating layer is included on a surface of the first layer that is opposite side to the second layer.

7. The stacked body according to claim 1, wherein the stacked body is used as a front panel of a display device.

8. A stacked body comprising a first layer, a second layer, a fourth layer, and a third layer in this order, wherein
a recovery at a cross-section of the second layer and the fourth layer, according to a nanoindentation method, is respectively 10% or more.

9. The stacked body according to claim 8, wherein the third layer includes a first main surface located on a fourth layer side, a second main surface opposite to the first main surface, and a side surface different from the first main surface and the second main surface; and
the fourth layer covers the side surface of the third layer.

10. The stacked body according to claim 9, wherein a ratio of a thickness of the side surface covered by the fourth layer, with respect to a thickness of the third layer, is 0.5 or more and 1.0 or less.

11. The stacked body according to claim 8, wherein a composite elastic modulus of the second layer is more than 0.05 GPa.

12. The stacked body according to claim 8, wherein a composite elastic modulus of the fourth layer is more than 0.05 GPa.

13. The stacked body according to claim 8, wherein a thickness of the second layer is 1 μm or more and 25 μm or less.

14. The stacked body according to claim 8, wherein a thickness of the fourth layer is 5 μm or more and 80 μm or less.

15. The stacked body according to claim 8, wherein the third layer is a glass substrate having a thickness in a range of 15 μm or more and 115 μm or less.

16. The stacked body according to claim 8, wherein the first layer is a resin film.

17. The stacked body according to claim 8, wherein a hard coating layer is included on a surface of the first layer that is opposite side to the second layer.

18. The stacked body according to claim 8, wherein the stacked body is used as a front panel of a display device.

19. A display device comprising:
a display panel, and
the stacked body according to claim 1 disposed on an observer side of the display panel.

20. A member for a stacked body used for the stacked body according to claim 1, wherein
the first layer and the second layer are stacked.
